(19) United States
(12) Patent Application Publication
(10) Pub. No.: US 2026/0215265 A1
(43) Pub. Date: Jul. 23, 2026

(54) INTEGRATED TEMPERATURE CONTROL SYSTEM FOR SUBASSEMBLIES

(71) Applicant: Adeia Semiconductor Bonding Technologies Inc., San Jose, CA (US)

(72) Inventors: Rajesh Katkar, Milpitas, CA (US); Ron Zhang, Sunnyvale, CA (US); Guilian Gao, Campbell, CA (US); Thomas Workman, San Jose, CA (US)

(21) Appl. No.: 19/425,292

(22) Filed: Dec. 18, 2025

Related U.S. Application Data
(63) Continuation of application No. 18/962,442, filed on Nov. 27, 2024.
(60) Provisional application No. 63/716,416, filed on Nov. 5, 2024.

(51) Int. Cl. H10W 40/43; H10W 40/47

(52) U.S. Cl. CPC H10W 40/43; H10W 40/47

(57) ABSTRACT

Embodiments herein provide for an integrated thermal control assembly comprising: a semiconductor device; a cold plate stacked vertically adjacent to the semiconductor device; and a heater device disposed adjacent to the semiconductor device and the cold plate.

### CROSS-REFERENCE TO RELATED APPLICATIONS

This application is a continuation of U.S. patent application Ser. No. 18/962,442, filed Nov. 27, 2024, which claims the benefit of U.S. Provisional Ser. No. 63/716,416, filed Nov. 5, 2024, each of which are hereby incorporated by reference herein in its entireties.

### FIELD

The present disclosure relates to advanced packaging for microelectronic devices, and in particular, temperature control systems for device packages and methods of manufacturing the same.

### BACKGROUND

Energy consumption poses a critical challenge for the future of large-scale computing as the world's computing energy requirements are rising at a rate that most would consider unsustainable. Some models predict that the information, communication and technology (ICT) ecosystem could exceed 20% of global electricity use by 2030, with direct electrical consumption by large-scale computing centers accounting for more than one-third of that energy usage. A significant portion of the energy used by such large-scale computing centers is devoted to cooling, since even small increases in operating temperatures can negatively impact the performance of microprocessors, memory devices, and other electronic components. While some of this energy is expended to operate the cooling systems that are directly cooling the chips (e.g., heat spreaders, heat pipes, etc.), energy consumption/costs for indirect cooling can also be quite staggering. Indirect cooling energy costs include, for example, cooling or air conditioning of data center buildings. Data center buildings can house thousands, to tens of thousands or more, of high performance chips in server racks, and each of those high performance chips is a heat source. An uncontrolled ambient temperature in a data center will adversely affect the performance of the individual chips, and the data center system performance as a whole.

Thermal dissipation in high-power density chips (semiconductor devices/die) is also a critical challenge as improvements in chip performance, e.g., through increased gate or transistor density due to advanced processing nodes, evolution of multi-core microprocessors, etc., have resulted in increased power density and a corresponding increase in thermal flux that contributes to elevated chip temperatures. Higher density of transistors also increases the length of metal wiring on the chips, which generates its own additional thermal flux due to Joule heating of these wires due to higher currents. These elevated temperatures are undesirable as they can degrade the chip's operating performance, efficiency, reliability, and amount of remaining life. Cooling systems used to maintain the chip at a desired operating temperature typically remove heat using one or more heat dissipation devices, e.g., thermal spreaders, heat pipes, cold plates, liquid cooled heat pipe systems, thermal-electric coolers, heat sinks, etc. One or more thermal interface materials (TIMs), such as, for example, thermal paste, thermal adhesive, or thermal gap filler, may be used to facilitate heat transfer between the surfaces of a chip and heat dissipation device(s). A thermal interface materials is any material that is inserted between two components to enhance the thermal coupling therebetween. Unfortunately, the combined thermal resistance of (i) the interfacial boundary regions between one or more TIMs and the chip and/or the heat dissipation device(s), and (ii) the thermal interface material itself can inhibit heat transfer from the chip to the heat dissipation devices, undesirably reducing the cooling efficiency of the cooling system. Generally speaking, there are multiple components between the heat dissipating sources (i.e., active circuitry) in the chips and the heat dissipation devices, each of which contributes to the system thermal resistance cumulatively along the heat transfer paths and raises chip junction temperatures from the ambient.

Such cooling systems can suffer from reduced cooling efficiency due to the design and manufacture of system components.

Additionally, communication between electronic components on a server rack, and between server racks themselves, is generally provided by copper wires. Unfortunately, these copper wires suffer from problems such as heat dissipation (due to their intrinsic resistance to current), communication signal attenuation, and bandwidth loss. As data demands grow, copper-based Serializer/Deserializer (SerDes) circuitry, which connects switching application-specific integrated circuits (ASICs) to pluggable transceivers, may be used to enable faster transmission, but faster ASICs require improved copper connections through more channels or higher speeds. However, as link density and bandwidth increase, a significant portion of system power and cost is consumed by driving signals from the ASICs to optical interconnects at the edge of the rack. The size limitations of ASIC ball grid array (BGA) packages (e.g. due to warpage concerns), require higher SerDes speeds to support increased bandwidth. This also results in higher power consumption because greater channel loss occurs at higher frequencies. One solution could be systems in which copper wires are replaced by optical fibers for signal transmission, which consumes relatively less energy with faster transmission speeds and improved reliability. As opposed to copper, multiple wavelengths carrying different signals can be simultaneously sent on a single fiber; such parallel signals using the same wires is not possible in copper wires. Optical fibers that enables signal transmission via an alternative medium (i.e., light) therefore mitigate the issues inherent to copper wires. The placement of a photonic integrated circuit (PIC) inside an electrical package increases the possibility of thermal crosstalk. While the thermal power from heaters and laser sources in a photonic die will affect the temperature map of the electrical package, the heat generated in electrical dies and the cooling mechanism of the overall system will affect the thermal behavior of the PIC. A complete thermal analysis from die to system level is therefore needed.

Co-packaged optics (CPO) is an approach that aims to enable high performance computing and networks by addressing challenges around bandwidth density, communication latency, copper reach, and power efficiency data-hungry networks by bringing key elements like optics and electronics needed for communication closer together. The primary application of CPOs is in front-end networks used for connecting servers in data centers. In order for signals to be transmitted optically, lasers or light emitting diodes (LEDs), such as micro LEDs, may be used to generate optical signals which propagate along the optical fibers. LEDs typically offer less bandwidth than lasers and are using with low bandwidth communication systems (e.g., operating up to about 250 MHz or around 200 Mb/s), whereas lasers are ideal for long distance high speed links (e.g., systems operating well over 10 GHz or 10 Gb/s). Common types of lasers used in optical communication systems include fabry-perot (F-P) lasers, distributed feedback (DFB) lasers, vertical cavity surface-emitting lasers (VCSELs), quantum dot lasers, etc. Transceivers (comprising an electronic integrated circuit (EIC) and a photonic integrated circuit (PIC)) may be used to convert between optical signals and electrical signals for compatibility with electronic circuitry. The placement of the PIC inside the electrical package increases the possibility of thermal crosstalk. While the thermal power from heaters (e.g., laser sources, LEDs, etc.) in the photonic die can affect the temperature map of the package, the heat generated in the electrical dies and the cooling mechanism of the overall system can affect the thermal behavior of the PIC. The optimal performance of lasers requires a narrow operating temperature range (for example, about 50° C. to 75° C.), and therefore lasers are susceptible to small temperature variations. For example, deviations from its optimal operating temperature range may shift the laser wavelength range outside of the designed wavelength range such that at least a part of the optical signal cannot be carried through the optical fiber. Upon processing by a transceiver, this may lead to an erroneous or attenuated electrical signal. Furthermore, any shift from the optimal operating temperature range may prevent the optical signal from being carried through the optical fiber resulting in shutdown of the system. Consequently, maintaining an operating temperature of a laser within an optimal temperature range is important to ensure correct operation is maintained.

In some systems, lasers may be integrated with high-performance devices with an optimum operating temperature in the range of 80° C. to 110° C. (e.g., central processing units (CPUs), graphical processing units (GPUs), neural processing unit (NPU), tensor processing unit (TPU), ASIC, high bandwidth memory (HBM), etc.). Cooling solutions for such systems are therefore shared between lasers and high-performance devices, across multiple servers sometimes spread across multiple server racks. A target temperature for the overall system may not be appropriate for specific devices, such as lasers which require a narrow operating temperature range, as discussed above. Moreover, if the high-performance devices operate while the laser devices are already at a lower end of their optimum operating temperature, the cooling solution may be triggered by the high-performance devices which could inadvertently cool the laser device to a temperature below the optimum range.

In some approaches, thermoelectric coolers (TECs) are attached to lasers to control the operating temperature (e.g., cooling or heating the laser using the Peltier effect). To do so, a TEC comprises two different materials connected by a metallic junction, between which a voltage difference is applied to either generate or absorb heat and create thermal flux or heat transfer between the two material based on the sign of the voltage difference applied. TECs are responsive and may be made of semiconductors and thus easily interfaced with electronic components. However, TECs present a large footprint (for example, 5×5 mm², or 10×10 mm²) compared to that of lasers (for example, 0.5×0.5 mm², or 2×2 mm²).

Accordingly, there exists a need in the art for providing dedicated temperature control for specific components in a relatively small footprint.

### SUMMARY

One general aspect includes an integrated thermal control assembly including a semiconductor device, a cold plate stacked vertically adjacent to the semiconductor device, and a heater device disposed adjacent to the semiconductor device and the cold plate.

Implementations of the integrated thermal control assembly may include one or more of the following features. The cold plate may comprise a perimeter sidewall, a top portion, a cavity divider, and coolant channels. The perimeter sidewall and the cavity divider may extend downwardly from the top portion to define portions of the coolant channels. The semiconductor device may be a laser device or an LED. The semiconductor device, the cold plate, and the heater device may be vertically stacked with the heater device disposed between the semiconductor device and the cold plate. The cold plate may be attached to a first side of the heater device (e.g., by direct dielectric bonds of direct hybrid bonds). The semiconductor device may be attached to a second side of the heater device (e.g., by direct dielectric bonds of direct hybrid bonds) opposite the first side of the heater device. The first side of the heater device may be exposed to at least one coolant channel.

Another general aspect includes an integrated thermal control assembly including a laser device and a heater device. The laser device is attached to the heater device by direct dielectric bonds or direct hybrid bonds.

Another general aspect includes an integrated thermal control assembly including a laser device and a cold plate attached to a backside of the laser device by direct dielectric bonds. The cold plate comprises a perimeter sidewall, a top portion, a cavity divider, and coolant channels. The perimeter sidewall and the cavity divider extend downwardly from the top portion to define portions of the coolant channels.

Another general aspect includes a method of manufacturing an integrated thermal control assembly. The method includes preparing a semiconductor device, a cold plate, and a heater device in an adjacent arrangement. The method further comprises directly bonding together the semiconductor device, the cold plate and the heater device to form the integrated thermal control assembly.

### BRIEF DESCRIPTION OF THE DRAWINGS

The above and other objects and advantages of the disclosure will be apparent upon consideration of the following detailed description, taken in conjunction with the accompanying drawings, in which:

FIG. 1 illustrates a device package with an external heat sink;

FIG. 2A is a schematic plan view of an example of a system panel, in accordance with embodiments of the present disclosure;

FIG. 2B is a schematic partial side view of a device package mounted on a printed circuit board (PCB), in accordance with embodiments of the present disclosure;

FIG. 2C is a schematic exploded isometric view of the device package in FIG. 2B;

FIG. 3 is a schematic sectional view of a example device package, in accordance with embodiments of the present disclosure, that may be used with the system panel;

FIG. 4 is a schematic sectional view of an integrated thermal control assembly of the device package, in accordance with embodiments of the present disclosure;

FIG. 5 is an isometric view of an exemplary cold plate.

FIG. 6A is a schematic sectional view of another integrated thermal control assembly of the device package, in accordance with embodiments of the present disclosure;

FIG. 6B is another schematic sectional view of the integrated thermal control assembly of FIG. 6A;

FIG. 7A is a schematic sectional view of another integrated thermal control assembly of the device package, in accordance with embodiments of the present disclosure;

FIG. 7B is another schematic sectional view of the integrated thermal control assembly of FIG. 7A;

FIG. 8A is a schematic sectional view of another integrated thermal control assembly of the device package, in accordance with embodiments of the present disclosure;

FIG. 8B is another schematic sectional view of the integrated thermal control assembly of FIG. 8A;

FIG. 9A is a schematic sectional view of another integrated thermal control assembly of the device package, in accordance with embodiments of the present disclosure;

FIG. 9B is another schematic sectional view of the integrated thermal control assembly of FIG. 9A;

FIG. 10A is a schematic sectional view of another integrated thermal control assembly of the device package, in accordance with embodiments of the present disclosure;

FIG. 10B is another schematic sectional view of the integrated thermal control assembly of FIG. 10A;

FIG. 11 is a schematic sectional view of another integrated thermal control assembly of the device package, in accordance with embodiments of the present disclosure;

FIG. 12 is a plan view of circuitry, in accordance with embodiments of the present disclosure;

FIG. 13A is a schematic sectional view of the circuitry of FIG. 12;

FIG. 13B is another schematic side sectional view of the circuitry of FIG. 12; and

FIG. 14 is a flow diagram showing a method of forming an integrated thermal control assembly, according to embodiments of the present disclosure.

The figures herein depict various embodiments of the present disclosure for purposes of illustration only. It will be appreciated that additional or alternative structures, assemblies, systems, and methods may be implemented within the principles set out by the present disclosure.

### DETAILED DESCRIPTION

As used herein, the term “substrate” means and includes any workpiece, wafer, or article that provides a base material or supporting surface from which or upon which components, elements, devices, assemblies, modules, systems, or features of the heat-generating devices, packaging components, and cooling assembly components described herein may be formed or mounted. The term “substrate” also includes semiconductor substrates that provide a supporting material upon which elements of a semiconductor device are fabricated or attached, and any material layers, features, and/or electronic devices formed thereon, therein, or therethrough. Examples of substrate material that may be used in applications that generate high thermal density include, but are not limited to, Si, GaN, SiC, InP, GaP, InGaN, AlGaInP, AlGaAs, etc.

As described below, the semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that forms the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active sides” and “non-active sides” are also used to describe surfaces of material layers or features formed on, in, or through the semiconductor substrate, whether or not the material layers or features are ultimately present in the fabricated or assembled device. For example, in some instances, the term “active side” is used to indicate a surface of a substrate that will in the future, but does not yet, include semiconductor device elements.

Spatially relative terms are used herein to describe the relationships between elements, such as the relationships between substrates, heat-generating devices, cooling assembly components, device packaging components, and other features described below. Unless the relationship is otherwise defined, terms such as “above,” “over,” “upper,” “upwardly,” “outwardly,” “on,” “below,” “under,” “beneath,” “lower,” “top,” “bottom” and the like are generally made with reference to the X, Y, and Z directions set forth by X, Y and Z axes in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” and the like, either alone or in combination with a spatially relevant term, include both relationships with intervening elements and direct relationships where there are no intervening elements. Furthermore, the term “horizontal” is generally made with reference to the X-axis direction and the Y-axis direction set forth in the drawings. The term “vertical” is generally made with reference to the Z-axis direction set forth in the drawings.

Various embodiments disclosed herein include bonded structures in which two or more elements are directly bonded to one another without an intervening adhesive (referred to herein as “direct bonding” or “directly bonded”). The resultant bonds formed by this technique may be described as “direct bonds”. In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. As discussed in more detail below, the process of direct bonding (e.g., direct dielectric bonding) provides a reduction of thermal resistance between a semiconductor device and a cold plate. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive or solder. The resultant bonds formed by this technique may be described as “hybrid bonds” and/or “direct hybrid bonds”. In some hybrid bonding embodiments, there are many first conductive features, each directly bonded to a second conductive feature, without any intervening adhesive or solder. In some embodiments, nonconductive features on the first element are directly bond to nonconductive features of the second element at room temperature without any intervening adhesive, which is followed by directly bonding of conductive features of the first element to conductive features of the second element via annealing at slightly higher temperatures (e.g., >100° C., >200° C., >250° C., >300° C., etc.), wherein the annealing causes the conductive features to expand faster than the non-conductive features and to bond together.

Unless otherwise noted, the terms “thermal control assembly” and “integrated thermal control assembly” generally refer to a semiconductor device, a heater device, and a cold plate attached together. Advantageously, integrated thermal control assemblies may provide cooling effects and/or heater effects to an adjacent device in order that an operating temperature of the adjacent device can be precisely controlled.

Typically, the cold plate is formed with recessed surfaces that define one or more fluid cavities (e.g., coolant chamber volume(s) or coolant channel(s)) between the cold plate and the semiconductor device. In embodiments where the cold plate is formed with plural fluid cavities, each fluid cavity may be defined by cavity dividers and/or sidewalls of the cold plate. For example, cavity dividers may be spaced apart from each other and extend laterally between opposing cold plate sidewalls (e.g., in one direction between a first pair of opposing cold plate sidewalls, or in two directions between orthogonal pairs of opposing cold plate sidewalls). The cavity dividers and the cold plate sidewalls may collectively define adjacent fluid cavities therebetween. The cold plate may comprise a polymer material. While it is preferred that the cold plate is formed of a material whose coefficient of linear thermal expansion (CTE) is the same as or similar to the bulk material of the semiconductor device, in some embodiments the cold plate may comprise one or more materials such as: polymer, copper, aluminum, silicon, glass, or ceramic, for example.

The cold plate may be attached to the semiconductor device and/or the heater device by use of an adhesive layer or by direct bonding or hybrid bonding. Direct bonding may include direct dielectric bonding techniques as described herein, and may give rise to direct dielectric bonds. Hybrid bonding may include hybrid bonding techniques as described herein, and may give rise to direct hybrid bonds. For example, the cold plate may include material layers and/or metal features that facilitate direct bonding or hybrid bonding with the semiconductor device. In some embodiments, the backside of the semiconductor device and/or the backside of the heater device is beneficially directly exposed to coolant fluids flowing through the integrated thermal control assembly, thus providing for direct heat transfer therebetween. It will be understood that “coolant fluid” may alternatively be referred to as “cooling fluid”. Unless otherwise noted, the cold plates described herein may be used with any desired fluid, e.g., liquid, gas, and/or vapor-phase coolants, such as water, glycol, etc. In some embodiments, the coolant fluid(s) may contain additives to enhance the conductivity of the coolant fluid(s) within the integrated thermal control assemblies. The additives may comprise, for example, nanoparticles of various types, such as carbon nanotubes, nanoparticles of graphene, and/or metal oxides. The concentration of these nanoparticles within the coolant fluid may be less than 1%, less than 0.2%, or less than 0.05%. The coolant fluids may also contain a small amount of glycol or glycols (e.g., propylene glycol, ethylene glycol, etc.) to reduce frictional shear stress and drag coefficient in the coolant fluid(s) within the integrated thermal control assembly. In some embodiments the coolant fluid may contain entirely glycol or glycols.

Exemplary fluids available for use in the various thermal solution embodiments include: water (either purified or deionized), a glycol (e.g., ethylene glycol, propylene glycol), glycols mixed with water (e.g., ethylene glycol mixed with water (EGW) or propylene glycol mixed with water (PGW)), dielectric fluids (e.g. fluorocarbons, polyalphaolefin (PAO), isoparaffins, synthetic esters, or very high viscosity index (VHVI) oils), or mineral oils. Additionally, depending upon design and operating conditions, these fluids may be used in single-phase liquid, single-phase vapor, two-phase liquid/vapor or two-phase solid/liquid. By adjusting the fluid selection and the relative fluid concentrations in the fluid mixtures, it is possible to alter the thermohydraulic and heat transfer properties by altering the temperatures where phase change occurs, enabling as meeting design temperature and pressure conditions for the component being cooled or warmed and the thermal solution being deployed. Additionally, different combinations of the fluid phases may be employed in various hybrid configurations to meet the particular cooling or warming needs of a respective implementation and still be within the scope of the contemplated embodiments.

Additionally, in some embodiments part or all the cooling is provided by gases. Exemplary gases include atmospheric air and/or one or more inert gases such as nitrogen. Atmospheric air may be taken to mean the mixture of different gases in Earth's atmosphere made up of about 78% nitrogen and 21% oxygen.

Depending on the design needs of a thermal solution system using the disclosed embodiments, engineered dielectric coolant fluids may be used. As used herein, a dielectric coolant fluid is a fluid that is thermally conductive but not electrically conductive. Some examples of dielectric fluids used for cooling semiconductors include: 3M™ Fluorinert™ Liquid FC-40—A non-flammable, dielectric fluid that can be used in direct contact with live electronics; 3M™ Novec™ Engineered Fluids—A non-flammable, dielectric fluid that can be used in direct contact with live electronics; Galden® PFPE (perfluoropolyether) products used as heat transfer fluids; EnSolv Fluoro HTF—A solvent with a high boiling point and low pour point that can be used for semiconductor wafer cooling. It is understood that in the selection of the coolant fluid, system design aspects such as operating temperatures and pressures, fluid flow rates, fluid viscosity, and other properties will require evaluation when selecting the appropriate coolant fluid.

In some embodiments, the coolant fluids may contain microparticles and/or nanoparticle additives to enhance the conductivity of the coolant fluid within the integrated thermal control assemblies. Nanofluids are engineered fluids prepared by suspending the nano-sized (1-100 nm) particles of metals/non-metals and their oxide(s) with a base/conventional fluid. The suspension of high thermal conductivity metals/non-metals and their oxides nanoparticles enhances the thermal conductivity and heat transfer ability, etc. of the base fluid. The additives to the underlying cooling fluid may comprise for example, nanoparticles of carbon nanotube, nanoparticles of graphene, or nanoparticles of metal oxides. When the coolant fluid contains microparticles, the microparticles are typically 10 microns or less in diameter. Silicon oxide microparticles may be used.

The volume concentration of these micro or nanoparticles within the coolant fluid may be less than 1%, less than 0.2%, or less than 0.05%. Depending upon the liquid and micro/nanoparticle type chosen for the coolant fluid, higher volume concentrations of 10% or less, 5% or less, or 2% or less may be used. The coolant fluids may also contain small amounts of glycol or glycols (e.g. propylene glycol, ethylene glycol etc.) to reduce frictional shear stress and drag coefficient in the coolant fluid within the integrated thermal control assembly. The availability of different base fluids (e.g., water, ethylene glycol, mineral or other stable oils, etc.) and different nanomaterials provide a variety of nanomaterial options for nanofluid solutions to be used in the various embodiments. These nanomaterial option groups such as aforementioned metals (e.g., Cu, Ag, Fe, Au, etc.), metal oxides (e.g., TiO₂, Al₂O₃, CuO, etc.), carbons (e.g. CNTS, graphene, diamond, graphite . . . etc.), or a mixture of different types of nanomaterials. Metal nanoparticles (Cu, Ag, Au . . . ), metal oxide nanoparticles (Al₂O₃, TiO₂, CuO), and carbon-based nanoparticles are commonly employed elements. Silicon oxide nanoparticles may also be used. Using coolant fluids with micro and/or nanoparticles when practicing the various embodiments disclosed herein can result in increased heat removal efficiencies and effectiveness.

The fluid control design aspects of specific embodiments may require the nanofluids to be magnetic to facilitate either movement or cessation of movement of the fluids within the semiconductor structures. Magnetic nanofluids (MNFs) are suspensions of a non-magnetic base fluid and magnetic nanoparticles. Magnetic nanoparticles may be coated with surfactant layers such as oleic acid to reduce particle agglomeration and/or settling. Magnetic nanoparticles used in MNFs are usually made of metal materials (ferromagnetic materials) such as iron, nickel, cobalt, as well as their oxides such as spinel-type ferrites, magnetite (Fe₃O₄), and so forth. The magnetic nanoparticles used in MNFs typically range in size from about 1 to 100 nanometers (nm).

This disclosure describes embodiments involving the architecture of system and component elements that can be employed to provide for the cooling and heating of semiconductor components, packaging, and boards. However, those skilled in the art will appreciate the disclosed components and arrangements can be deployed and used in scenarios where component heat up or thermal warm up is desired for a component that is currently outside the low end of the desired operational range. Components that are outside the low end of their operational range can, if started in a cold environment, experience thermal warping or cracking up to and including thermal overexpansion and contact separation that may impair the successful operation of the system. Therefore, in these scenarios, the architectures and embodiments disclosed herein can be used where the indirect thermal solutions supporting them are repurposed or operated in a hybrid configuration to provide warming fluids or heat transfer media to accomplish the warm-up or heat-up scenario. These scenarios are controlled by systems not shown here to bring temperatures up at a speed or timing that enables the materials to avoid the excessive thermal expansion or unequal thermal expansion that may occur among the materials of the semiconductor or packaging being serviced by the thermal solution. Once the component or packaging is brought up into the normal operating range, it can be safely started and brought to a useful operational state.

Considering the warm-up or heat-up embodiments introduced above, the balance of this disclosure and terms used should be viewed in a light that also considers the design option for such warm-up or heat-up. Thus, where terms such as cooling channel, cooling chamber volume, and cooling port are used, for example, such terms could also be considered as a thermal control channel, a thermal control volume, or a thermal control port, respectively. A person of skill would understand that heat flux or heat transfer would go in a different direction, but the design concepts are similar and can be successfully employed in the various embodiments.

A heater device may comprise a resistive wire (e.g., metal or alloy wire) embedded in a semiconductor material (e.g., silicon) that dissipates heat when a current is passed through the resistive wire. Therefore, the heat is intentionally generated by the heater device 205 for the purpose of increasing a temperature of another device, such as a semiconductor device. The heater device may comprise one or more resistors to provide Joule effect-based heating to the semiconductor device. To provide heat, the heater device may be electrically connected to the semiconductor device or other circuitry to provide electrical power to the resistive wire and/or the one or more resistors (e.g., using through silicon via (TSV), or other connection types).

The term “adjacent” is taken to mean that two of more devices or components of the present disclosure are next to each other such one is above, below, or beside another. Furthermore, adjacent devices or components may be separated by intervening devices, components, or substrates while still being considered adjacent to one another. In the following disclosure, it will be understood that any two or more devices or components which are defined as being adjacent may alternatively be defined as “directly adjacent”. Directly adjacent is taken to mean that at least two components or devices are contacting each other with no intervening component, device, or substrate therebetween.

In some embodiments, a cooling channel is a liquid cooling channel, and a liquid may flow through the liquid cooling channel. In some embodiments, the liquid may comprise a water and/or glycol (e.g., propylene glycol, ethylene glycol, and mixtures thereof).

As described below, coolant fluid flowing through a cold plate may be used to control the temperature of semiconductor devices. The fluid flowing across the surface of the semiconductor device absorbs heat and conducts heat away from the semiconductor device.

This disclosure includes embodiments involving optical communication using LED or laser devices (e.g., laser diodes) which have a narrow range of optimal operating temperatures. However, it will be understood that the embodiments described herein may equally be applied to other devices which have a narrow range of optical operating temperatures instead of laser devices. For example, certain embodiments may be applied to micro-electro-mechanical-systems (MEMS) devices in order to control the operating temperature to remain within a specific temperature range.

Examples of laser devices (e.g., laser diodes) of certain embodiments include: F-P lasers, DFB lasers, VCSELs, quantum dot lasers, double heterostructure lasers, quantum well lasers, quantum cascade lasers, and inter-band cascade lasers. It will be understood that such laser devices may be co-packaged as a photonic integrated circuit (PIC) that integrates multiple optical based components onto a single platform to perform functions related to the generation, manipulation and detection of light. Such PICs may include: a laser, an input coupler, an optical modulator, an optical waveguide, a photonic crystal, optical fibers, a photo diode, and an optical ring resonator.

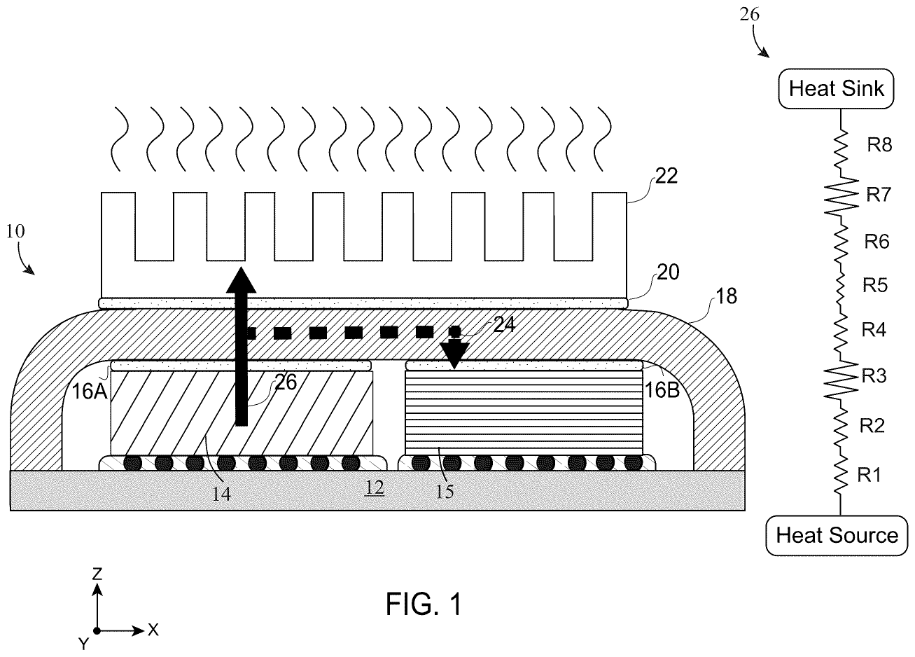

FIG. 1 is a schematic side view of a device package 10 and a heat sink 22 attached to the device package 10. The device package 10 typically includes a package substrate 12, a first device 14, a device stack 15, a heat spreader 18, and first TIM layers 16A, 16B thermally coupling the first device 14 and the device stack 15 to the heat spreader 18. The device package 10 is thermally coupled to the heat sink 22 through a second TIM layer 20. The TIM layers 16A, 16B, 20 facilitate thermal contact between components in the device package 10 and between the device package 10 and the heat sink 22.

As heat flux density increases with increasing power density in advanced semiconductor devices, the cumulative thermal resistance of the system illustrated in FIG. 1 is increasingly problematic as heat cannot be dissipated quickly enough to allow semiconductor devices to run at optimal power. Consequently, the energy efficiency of semiconductor devices is reduced. Furthermore, heat is transferred between semiconductor devices within the device package 10, as shown with heat transfer path 24 (illustrated as a dashed line), where heat may be undesirably transferred from the first device 14 having a high heat flux, such as a central processing unit (CPU) or a graphical processing unit (GPU), to the device stack 15 having low heat flux, such as memory, through the heat spreader 18.

For example, as shown in FIG. 1, each device package component and the respective interfacial boundaries therebetween have a corresponding thermal resistance that forms heat transfer path 26 (illustrated by arrow 26 in FIG. 1). The right-hand side of FIG. 1 illustrates the heat transfer path 26 as a series of thermal resistances R1-R8 between a heat source and a heat sink. Here, R1 is the thermal resistance of the bulk semiconductor material of the first device 14. R3 and R7 are the thermal resistances of the first TIM layers 16A, 16B and the second TIM layer 20, respectively. R5 is the thermal resistance of the heat spreader 18. R2, R4, R6, and R8 represent the thermal resistance at the interfacial region of the components (e.g., contact resistances). In a typical cooling system, R3 and R7 may account for 80% or more of the cumulative thermal resistance of the heat transfer path 26, and R5 may account for 5% or more. R1 of the first device 14 and R2, R4, R6, and R8 of the interfaces account for the remaining cumulative thermal resistance. Accordingly, embodiments described herein provide for integrated thermal control assemblies embedded within a device package. The embedded cooling assemblies shorten the thermal resistance path between a semiconductor device and a heat sink and reduce thermal communication between semiconductor devices disposed in the same device package, such as described in relation to the figures below.

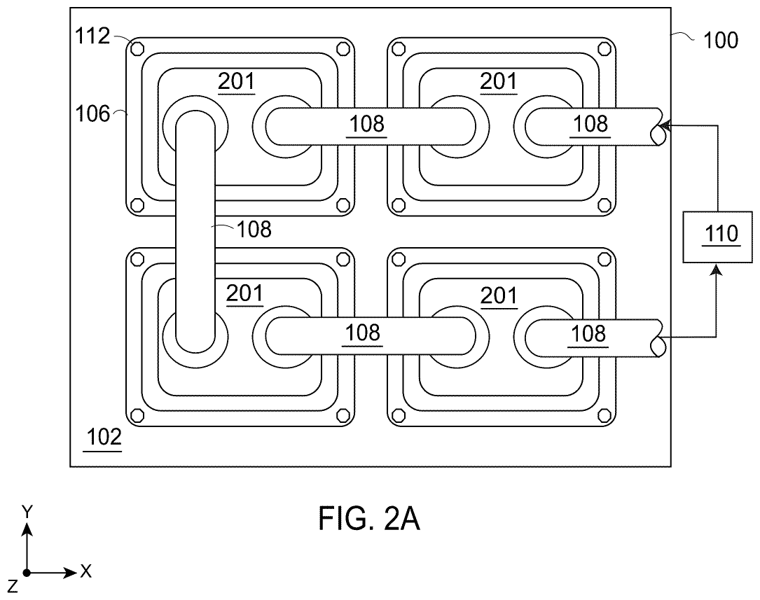

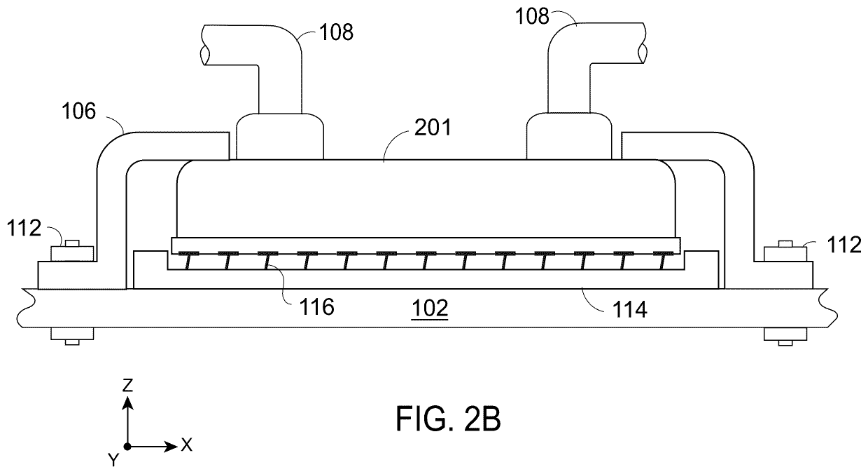

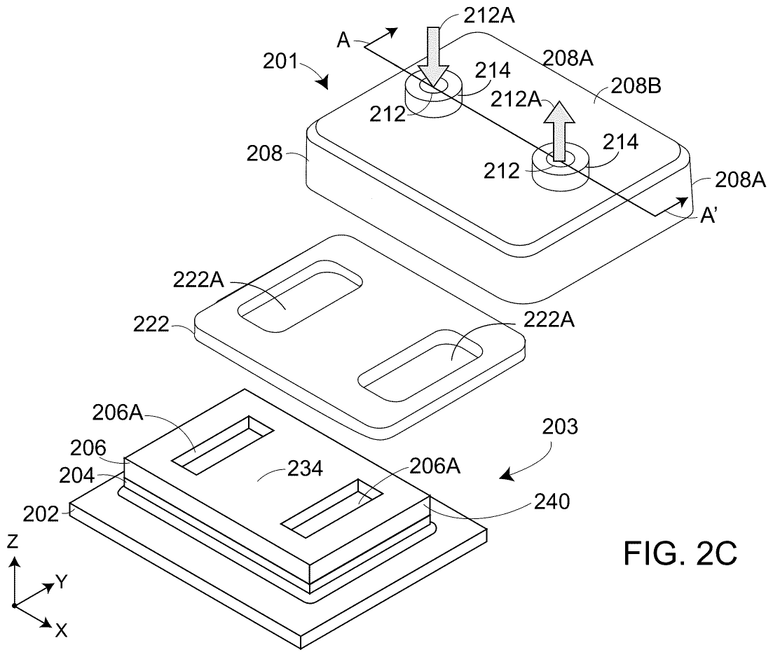

FIG. 2A is a schematic plan view of an example of a system panel 100, in accordance with embodiments of the present disclosure. Generally, the system panel 100 includes a PCB 102, a plurality of device packages 201 mounted to the PCB 102, and a plurality of coolant lines 108 fluidly coupling each of the device packages 201 to a coolant source 110. It is contemplated that coolant fluid may be delivered to each of the device packages 201 in any desired fluid phase, e.g., liquid, vapor, gas, or combinations thereof, and may flow out from each device package 201 in the same phase or a different phase. In some embodiments, the coolant fluid is delivered to the device packages 201 and returned therefrom as a liquid, whereby the coolant source 110 may comprise a heat exchanger or chiller to maintain the coolant fluid at a desired temperature. In other embodiments, the coolant fluid may be delivered to the device packages 201 as a liquid, vaporized to a vapor within the device packages 201, and returned to the coolant source 110 as a vapor. In those embodiments, the device packages 201 may be fluidly coupled to the coolant source 110 in parallel, and the coolant source 110 may include or further include a compressor (not shown) for condensing the received vapor to a liquid form.

FIG. 2B is a schematic partial sectional side view of a portion of the system panel 100 of FIG. 2A. As shown, each device package 201 is fluidly coupled to the plurality of coolant lines 108 and is disposed in a socket 114 of the PCB 102 and connected thereto using a plurality of pins 116, or by other suitable connection methods, such as solder bumps (not shown). The device package 201 may be seated in the socket 114 and secured to the PCB 102 using a mounting frame 106 and a plurality of fasteners 112, e.g., compression screws, collectively configured to exert a relatively uniform downward force on the upward facing edges of the device package 201. The uniform downward force ensures proper pin contact between the device package 201 and the socket 114.

FIG. 2C is a schematic exploded isometric view of an example device package 201, in accordance with embodiments of the present disclosure. Generally, the device package 201 includes a package substrate 202, an integrated thermal control assembly 203 disposed on (e.g., attached to) the package substrate 202, and a package cover 208 disposed on a peripheral portion of the package substrate 202. Suitable materials that may be used in the package cover 208 include copper, aluminum, metal alloys, etc. The package cover 208 extends over the integrated thermal control assembly 203 so that the integrated thermal control assembly 203 is disposed between the package substrate 202 and the package cover 208. The integrated thermal control assembly 203 typically includes a semiconductor device 204, a cold plate 206, and a heater device 205 disposed adjacent to the semiconductor device 204 and the cold plate 206. In some embodiments, the cold plate 206 may comprise substrate material like silicon, glass, ceramic, etc. Although the lateral dimensions (or footprint) of the cold plate 206 are shown to be the same or similar to the lateral dimensions (or footprint) of the semiconductor device 204 and the heater device 205, the footprint of the cold plate 206 may be smaller or larger in one or both directions when compared to the footprint of the semiconductor device 204 and the heater device 205. Further, the footprint of the heater device 205 may be greater than or less than the footprint of the semiconductor device 204 and/or the cold plate 206.

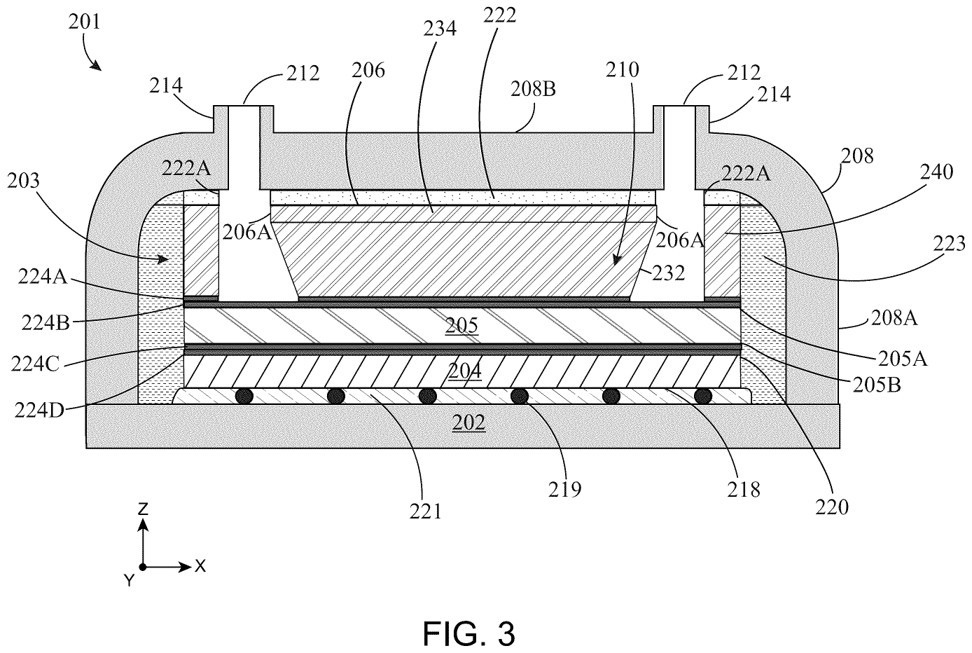

As shown, the device package 201 further includes a sealing material layer 222 that forms a coolant fluid impermeable barrier between the package cover 208 and the integrated thermal control assembly 203 that prevents leaking of the coolant fluid outside of the cooling assembly and prevents coolant fluid from reaching an active side 218 (discussed below in relation to FIG. 3) of the semiconductor device 204 and causing damage thereto. In some embodiments, the sealing material layer 222 comprises an adhesive material that reliably attaches the package cover 208 to the integrated thermal control assembly 203. In some embodiments, the sealing material layer 222 comprises a polymer or epoxy material that extends upwardly from the package substrate 202 to encapsulate and/or surround at least a portion of the semiconductor device 204. In some embodiments, the sealing material layer 222 may also comprise conductive material, e.g., solder. In other embodiments, the sealing material layer 222 is formed from a molding compound, e.g., a thermoset resin, that when polymerized, forms a hermetic seal between the package cover 208 and the cold plate 206. Here, the coolant fluid is delivered to the cold plate 206 through openings 222A disposed through the sealing material layer 222. As shown, the openings 222A are respectively in registration and fluid communication with inlet and outlet openings 212 of the package cover 208 thereabove and inlet and outlet openings 206A in the cold plate 206 therebelow.

It will be understood that the openings are shown in a section view. The openings may have any cross-sectional shape that allows fluid to flow therethrough (e.g., rectangular, square, hexagonal or circular cross-sections). For example, the inlet and outlet openings 206A of the cold plate 206 may form an elongated shape extending from one side of the cold plate 206 to another side of the cold plate 206. For example, the inlet and outlet openings 206A may form any shape having a length greater than a width in the X-Y plane (e.g., a rectangular or a trapezoidal shape). A shape in the X-Y plane of the openings 222A disposed through the sealing material layer 222 may be substantially the same as the shape of the inlet and outlet openings 206A of the cold plate 206 in the same place. Furthermore, it will be understood that all references to an opening throughout the present disclosure refer to an opening defined by a sidewall (e.g., opening sidewall), unless otherwise indicated.

In some embodiments, gaps formed between the inside walls of the package cover 208 and the integrated thermal control assembly 203 may be filled (partially or completely) with a molding material 223. The molding material 223 may encapsulate the integrates cooling assembly 203 to improve structural stability, for example.

The package substrate 202 can include a rigid material, such as an epoxy or resin-based laminate, that supports the integrated thermal control assembly 203 and the package cover 208. The package substrate 202 may include conductive features disposed in or on the rigid material that electrically couples the integrated thermal control assembly 203 to a system panel, such as the PCB 102.

FIG. 3 is a schematic sectional view in the X-Z plane of the device package 201, taken along line A-A′ of FIG. 2C.

As shown in FIG. 3, the cold plate 206 comprises perimeter sidewall 240, a top portion 234, a cavity divider 230, and coolant channels 210. The perimeter sidewall 240 and the cavity divider 230 extend downwardly from the top portion 234 to define portions of the coolant channels 210 of the integrated thermal control assembly 203.

In some embodiments, the semiconductor device 204 may comprise a sensor to measure the temperature of the semiconductor device 204 in real time so as to determine whether the semiconductor device 204 needs heating or cooling to be operated in e.g., an optimum temperature range or a range encompassing an optimum temperature range.

The cold plate 206 and the heater device 205 may collectively control a temperature of the semiconductor device 204 to remain within a predetermined range (e.g., an optimum temperature range, a temperature range encompassing the optimum temperature range). In some embodiments, one of the cold plate 206 or the heater device 205 may control the temperature of the semiconductor device 204 within a predetermined range (e.g., an optimum temperature range, a temperature range encompassing the optimum temperature range). In some embodiments, the predetermined range of temperature is 40 (degrees Celsius) ° C. to 110° C., 50° C. to 110° C., 80° C. to 110° C., 40° C. to 75° C., 50° C. to 75° C., 50° C. to 70° C., for example. By using at least one of the cold plate 206 and the heater device 205, it is possible to locally control the temperature across the semiconductor device 204 and set said temperature within the optimum temperature range in which the semiconductor device 204 provides, when in operation, an optimum optical and/or electronics performance. This is particularly important when the semiconductor device 204 comprises a laser diode (such as in an optoelectronic transceivers comprising a photonic integrated circuit) in which a small temperature deviation may cause the temperature to be outside the optimum temperature range and the shutdown of optical fiber-mediated communication between electronic components.

As illustrated in FIG. 3, the laser (or LED) device 204 includes the frontside 218 and backside 220, opposite the frontside 218. As shown, the frontside 218 is positioned adjacent to and facing towards the package substrate 202. In embodiments where the semiconductor device 204 is a laser device 204, the package substrate 202 may be an optical waveguide (e.g., optical waveguide 202) and the laser device 204 may be directly exposed to the waveguide 202. In other embodiments where the semiconductor device 204 is a laser device 204, the package substrate 202 may be an interposer with optical waveguides. In embodiments where the semiconductor device 204 is an electronic device, such as a MEMS device, the frontside 218 may include device components, e.g., transistors, resistors, and capacitors, formed thereon or therein, and the frontside 218 be electrically connected to the package substrate 202 by use of conductive bumps 219 (e.g., using flip chip technology). The conductive bumps may be encapsulated by a first underfill layer 221 disposed between the MEMS device and the package substrate 202. The first underfill layer 221 may comprise a cured polymer resin or epoxy, which provides mechanical support to the conductive bumps 219 and protects against thermal fatigue. In some embodiments, the frontside 218 of the MEMS device may be electrically connected to another package substrate, another active die, or another passive die (e.g., interposer) using hybrid bonding or conductive bumps 219. Although FIG. 3 illustrates the laser device 204 is attached to the substrate 202 using flip chip technology, the laser device 204 may alternatively be attached to the substrate 202 by direct bonding or hybrid bonding, as described herein. It will be understood that the semiconductor device 204 may be any device the temperature of which must be controlled to remain within a specific range. For example, the semiconductor device 204 may be a laser device (e.g., laser diode) or a MEMS device. However, for simplicity, the semiconductor device 204 will generally be referred to as a laser device 204 from hereon.

The cold plate 206 may be disposed above the package substrate 202 adjacent to the heater device 205 and the laser device 204. For example, the laser device 204 and the heater device 205 may both be disposed between the cold plate 206 and the package substrate 202, with other arrangements being discussed in more detail below. Similar to the laser device 204, the heater device 205 comprises a frontside 205B and a backside 205A opposite to the frontside 205A. In FIG. 3, the backside 205A of the heater device 205 faces the cold plate 206 and the frontside 205B of the heater device 205 faces the optical waveguide 202 (with other arrangements discussed below). The waveguide 202 may direct light generated by the laser device 204 (e.g., in a direction substantially perpendicular to the backside 220 of the laser device 204).

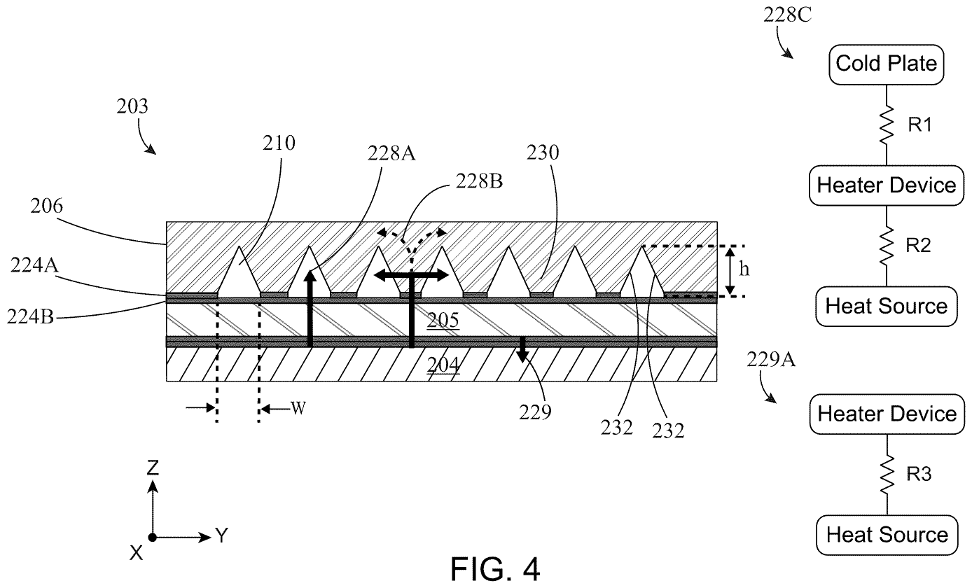

Here, the cold plate 206 comprises a top portion 234, a cavity divider 230, and a sidewall 240 (e.g., a perimeter sidewall defining a perimeter of the cold plate 206). The perimeter sidewall 240 and the cavity divider 230 extend downwardly from the top portion 234 to define portions of the coolant channels 210. In some embodiments, the perimeter sidewall 240 and the cavity divider 230 extend downwardly from the top portion 234 to the backside of the heater device 205 to define coolant channels 210 therebetween. The cold plate 206 may comprise plural cavity dividers 230 each extending downwardly from the top portion 234. The cavity dividers 230 may alternatively be referred to as support features 230, which provide structural support to the integrated thermal control assembly 203. The cavity dividers 230 may extend laterally and in parallel between an inlet opening 206A of the cold plate 206 and an outlet opening 206A of the cold plate 206 to define the coolant channels 210 therebetween. It should be appreciated that the cold plate 206 may comprise one cavity divider 230 which forms two coolant channels (e.g., one coolant channel on either side of the cavity divider 230) by means of the cavity divider 230 and portions of the perimeter sidewall 240. More specifically, coolant channels 210 may be formed between the cavity divider 230 and a portion of the perimeter sidewall 240 extending parallel to or in the same general direction as the cavity divider 230. Alternatively, in other embodiments, the cold plate 206 may comprise plural cavity dividers 230, for example two cavity dividers, five cavity dividers, or six cavity dividers (as illustrated in FIG. 4). In such examples, the cold plate 206 comprises more than two coolant channels 210, for example three coolant channels, four coolant channels, seven coolant channels, or more, defined between the cavity dividers 230 and/or the cavity divider(s) 230 and the perimeter sidewall 240. In some embodiments, at least one of the cavity dividers 230 may extend discontinuously between the inlet opening 206A and the outlet opening 206A (in the X-axis direction) to form a discontinuous cavity divider. A discontinuous cavity divider may be formed of plural segments between which coolant fluid may flow. The segments of a discontinuous cavity divider may have the same or different lengths in the X-axis direction. One or more segments may form a post.

The cavity dividers 230 comprise cavity sidewalls 232 which form surfaces of corresponding coolant channels 210. In embodiments where plural cavity dividers 230 extend in parallel to each other, cavity sidewalls 232 of adjacent cavity dividers 230 are opposite (e.g., facing) each other. In embodiments comprising a single cavity divider 230, a first cavity sidewall may be opposite (e.g., face) a first portion of the perimeter sidewall 240 extending parallel to and facing the first cavity sidewall. A second cavity sidewall may be opposite (e.g., face) a second portion of the perimeter sidewall 240 extending parallel to and facing the second cavity sidewall. The first portion of the perimeter sidewall 240 may be an opposite side of the cold plate 206 to the second portion of the perimeter sidewall 240. For example, in embodiments where the cold plate 206 is rectangular, first and second opposing sides of the rectangular cold plate 206 form the first and second portions of the perimeter sidewall 240.

The cavity dividers 230 may be continuous cavity dividers which extend continuously (e.g., in the X-axis direction) between the inlet opening 206A and the outlet opening 206A of the cold plate 206.

With reference to FIG. 3 and FIG. 4, coolant channels 210 may be defined by:
the backside 205A of the heater device 205, which forms lower coolant channel surfaces;
portions of the perimeter sidewall 240 extending in the Y-axis direction, which form end surfaces of the coolant channels 210;
the cavity sidewalls 232, which form inner surfaces of the coolant channels 210 in the X-axis direction; and
portions of the perimeter sidewall 240 extending in the X-axis direction, which form outer surfaces of the coolant channels 210 in the X-axis direction.

As shown in FIG. 4 and described in further detail below, the cavity sidewalls 232 can be formed at an acute angle with respect to the backside 220 of the laser device 204 such that upper portions of opposing (e.g., facing) cavity sidewalls 232 meet. Therefore, the cavity sidewalls 232 and the backside 220 of the laser device 204 collectively define a triangular cross-section of the coolant channel 210. However, it will be understood that the coolant channel 210 may be formed with different shaped cross-sections. For example, one or more coolant channels may be formed with trapezoidal, rectangular, or semi-circular cross-section, or a combination thereof.

In some embodiments, the backside 220 of the laser device 204 comprises a corrosion protective layer (not shown). The corrosion protective layer may be a continuous layer disposed across the entire backside 220 of the laser device 204, such that the cold plate 206 is attached thereto. Beneficially, the corrosion protective layer provides a corrosion-resistant barrier layer, thus preventing undesired corrosion of the laser device 204 (e.g., the semiconductor substrate material which might otherwise be in direct contact with coolant fluid flowing through a coolant chamber volume 210).

One or more coolant chamber volumes may include one or more coolant channels. The coolant channels may extend between a single inlet opening and a single outlet opening of the cold plate 206, such that the coolant chamber volume(s) and/or coolant channel(s) share the same inlet and outlet openings. In other embodiments, multiple inlet and/or outlet openings may be coupled to the coolant chamber volume(s).

In embodiments having plural coolant chamber volumes and/or plural coolant channels, each coolant chamber volume and/or coolant channel may be connected between a separate inlet opening and a separate outlet opening. In such embodiments, the coolant fluid may be directed to the separate inlet openings and from the separate outlet openings using a manifold disposed above the openings in the Z-axis direction. In some embodiments, a gasket may be used to seal a gap between the manifold and the cold plate inlet/outlet openings. The gasket may be made of rubber (e.g., neoprene, nitrile, ethylene propylene diene monomer, or silicon rubber) or similar such material. For example, the gasket may be an o-ring. The gasket may be attached between a lower surface of the manifold and an upper surface of the cold plate facing the manifold using an adhesive. The gasket may provide a water tight seal to direct coolant fluid from the manifold into the cold plate inlet/outlet openings while preventing coolant fluid from leaking onto exterior surfaces of the integrated thermal control assembly 203. In some embodiments, the manifold is attached to one or more cold plates using one or more corresponding gaskets.

Referring to FIG. 4, a height h in the Z-axis direction of the coolant chamber volume(s) and or coolant channel(s) may be greater than 100 μm, 100 μm-1000 μm, or 100 μm-700 μm. A width w in the Y-axis direction of each coolant channel 210 may be greater than 100 μm, 100 μm-1000 μm, or 100 μm-700 μm. For example, the width w of each coolant channel 210 may be greater than the height h thereof. In some embodiments, the width w of each coolant channel 210 may, at the widest portion, which may be taken as a base of the triangular shape of the coolant chamber channels 210 shown in FIG. 4, range from 0.2 mm to 5 mm. More specifically, the width w of a coolant channel 210 may range from 0.5 to 1.5 mm. The width w of a coolant channel 210 may also be between 1 and 5 mm.

A cross-section of a coolant channel 210 in the Y-Z plane may be wide enough to allow for a pressure drop of 0 -20 psi, 3-15 psi, or 4-10 psi.

In some embodiments, preparing a desired surface roughness of the sidewalls of each coolant channel 210 may include depositing an organic layer on a photoresist layer after cold plate features have been etched to form a micro-masking layer, such as between 1 to 30 nm. The micro-masking layer may be dry etched to form the desired surface roughness, such as between 0.1 to 3.0 nm. Advantageously, providing sidewalls with surface roughness increases the likelihood of fluid being directed towards and contacting the backside 220 of the semiconductor device 204 (e.g., by disrupting a hydrodynamic boundary layer of fluid between the sidewall and the coolant fluid).

In FIG. 3, the laser device (or LED device) 204, the cold plate 206, and the heater device 205 may be vertically stacked with the heater device 205 disposed between the laser device 204 and the cold plate 206. The cold plate 206 may be attached to a first side (e.g., backside 205A) of the heater device 205. The laser device 204 may be attached to a second side (e.g., frontside 205B) of the heater device 205 opposite the first side of the heater device 205. The first side of the heater device 205 may be exposed to at least one coolant channel 210. That is, the first side of the heater device 205 may be exposed to the coolant channels 210 such that heat dissipated directly from the heater device 205, and heat dissipated from the laser device 204 via the heater device 205, may be absorbed by coolant fluid flowing through the coolant channels 210.

With reference to FIG. 3, the cold plate 206 may be attached to the backside 205A of the heater device 205 without the use of an intervening adhesive. For example, the cold plate 206 may be directly bonded to the backside 205A of the heater device 205, such that the cold plate 206 and the backside 205A of the heater device 205 are in direct contact. For example, in some embodiments, one or both of the cold plate 206 and the backside 205A of the heater device 205 may comprise a dielectric material layer, e.g., a first dielectric material layer 224A and a second dielectric material layer 224B, respectively, and the cold plate 206 may be directly bonded to the backside 205A of the heater device 205 through bonds formed between the first and/or second dielectric material layers 224A, 224B. In some embodiments, one of the cold plate 206 or the backside 205A of the heater device 205 may comprise a thin bonding dielectric layer (e.g., silicon nitride, etc.) and other element(s) may not include any such explicit bonding dielectric layer (or can have only a native oxide layer). The first and second dielectric material layers 224A, 224B may be continuous or non-continuous. For example, the first dielectric material layer 224A may be disposed only on lower surfaces of the cold plate 206 facing the backside 205A of the heater device 205. The frontside 205B of the heater device 205 may be directly bonded to the backside 220 of the laser device 204 using the same technique with third and fourth dielectric material layers 224C, 224D.

With reference to FIG. 4, described below, portions of the first dielectric material layer 224A may be disposed only on lower surfaces of the cavity dividers 230 (e.g. support features 230) and the perimeter sidewall 240. Beneficially, directly bonding the cold plate 206 to the heater device 205, and the heater device 205 to the laser device 204, as described above, reduces the thermal resistance therebetween and increases the efficiency of heat transfer from the laser device 204 through the heater device 205 to the cold plate 206. Furthermore, the efficiency of heat transfer from the heater device 205 to the laser device 204 is improved. In particular, thermal resistance is reduced by directly bonding lower surfaces of the cavity dividers 230 facing the heater device 205 to the backside 205A of the heater device 205, and the frontside 205B of the heater device 205 facing the laser device 204 to the backside 220 of the laser device 204.

In some embodiments, the heater device 205 may be disposed between and laterally adjacent to both the cold plate 206 and the laser device 204. In such embodiments, the cold plate 206, the laser device 204, and the heater device 205 may share the same second dielectric material layer 224B.

In some embodiments, the cold plate 206 may be attached to the backside 205A of the heater device 205 with the use of an intervening adhesive. Similarly, the heater device 205 may be attached to the backside 220 of the laser device 204 with the use of an intervening adhesive.

It will be understood that the spatial arrangement of the cold plate 206, the heater device 205, and the laser device 204 (e.g., as depicted in FIG. 3) may be modified. For example, the cold plate 206 may be spaced apart from the heater device 205 through one or more layers (e.g., further semiconductor devices), resulting in the increase in distance between the cold plate 206 and the heater device 205 and an increase in distance between the cold plate 206 and the laser device 204. Similarly, the heater device 205 may be spaced apart from the laser device 204 through one or more layers (e.g., further semiconductor devices), resulting in the increase of a distance between the heater device 205 and the laser device 204 and an increase in distance between the cold plate 206 and the laser device 204.

FIG. 4 is a schematic sectional view in the Y-Z plane of the integrated thermal control assembly 203. In FIG. 4, the cold plate 206 comprises a patterned side that faces towards the heater device 205 and an opposite side that faces towards the package cover 208 (not shown). The patterned side comprises a coolant chamber volume having plural coolant channels 210, which extend laterally (along the X-axis direction in FIG. 4) between the inlet and outlet openings of the cold plate 206. Each coolant channel 210 comprises cavity sidewalls that define a corresponding coolant channel 210. Portions of the cold plate 206 between the cavity sidewalls 232 form the support features 230 (e.g., cavity dividers 230). The support features 230 (e.g., cavity dividers 230) provide structural support to the integrated thermal control assembly 203 and disrupt laminar fluid flow (e.g., due to surface roughness of the sidewalls) at the interface of the coolant and the backside 205A of the heater device 205, resulting in increased heat transfer therebetween. Furthermore, by introducing plural coolant channels 210 to define separate coolant flow paths, an internal surface area of the cold plate 206 is increased, which further increases the efficiency of heat transfer.

In FIG. 4, arrows 228A, 228B, and 229 illustrate three different heat transfer paths in the integrated thermal control assembly 203. A first heat transfer path illustrated by arrow 228A shows heat generated by the laser device 204 transferring from the semiconductor material of the laser device 204, through the heater device 205, and to coolant fluid flowing through the cold plate 206. A second heat transfer path illustrated by arrows 228B shows heat generated by the laser device 204 being transferred from semiconductor material (e.g., silicon material) of the laser device 204, through the heater device 205, to semiconductor material (e.g., silicon material) of the cold plate 206 structure, propagated throughout the semiconductor material of the cold plate 206 structure (shown as dashed lines), and being transferred into coolant fluid flowing through the cold plate 206. A third heat transfer path illustrated by arrow 229 shows heat which is purposely generated by the heater device 205 being transferred from the resistive wire and/or the one or more resistors of the heater device 205 to the laser device 204 therebelow. A thermal resistance of the first and second heat transfer paths 228A, 228B is illustrated by heat transfer path 228C, which is shown as a first thermal resistance R1 between the cold plate 206 and the heater device 205, and a second thermal resistance R2 between the heater device 205 and a heat source. A thermal resistance of the third heat transfer path 229 is illustrated by heat transfer path 229A, which is shown as third thermal resistance R3 between a heater device and a heat source. It can be seen that the heat transfer paths of the integrated thermal control assembly 203 are reduced compared to the heat transfer path 26 of the device package 10 of FIG. 1, due to the direct bonding discussed above.

In some embodiments, the cold plate 206 may be attached to the heater device 205 using a hybrid bonding technique, where bonds are formed between the first and second dielectric material layers 224A, 224B (see FIG. 3) and between metal features, such as between first metal pads and second metal pads, disposed in the dielectric material layers 224A, 224B. Similarly, the heater device 205 may be attached to the laser device 204 using a hybrid bonding technique, where bonds are formed between the third and fourth dielectric material layers 224C, 224D (see FIG. 3) and between metal features, such as between third metal pads and fourth metal pads, disposed in the dielectric material layers 224C, 224D. Advantageously, by using hybrid bonding techniques, interconnections may be formed between the cold plate 206 and the semiconductor device 204 using the first and second metal pads.

Suitable dielectrics that may be used as the first, second, third, and fourth dielectric material layers 224A, 224B, 224C, 224D include silicon oxides, silicon nitrides, silicon oxynitrides, silicon carbon nitrides, metal-oxides, metal-nitrides, silicon carbide, silicon oxycarbides, silicon oxycarbonitride, diamond-like carbon (DLC), or combinations thereof. In some embodiments, at least one of the dielectric material layers 224A, 224B, 224C, 224D are formed of an inorganic dielectric material, e.g., a dielectric material substantially free of organic polymers. Typically, at least one of the dielectric layers are deposited to a thickness greater than the thickness of a native oxide, such as about 1 nanometer (nm) or more, 5 nm or more, 10 nm or more, 50 nm or more, or 100 nm or more. In some embodiments, at least one of the layers are deposited to a thickness of 3 micrometers or less, 1 micrometer or less, 500 nm or less, such as 100 nm or less, or 50 nm or less. Dielectric material and thickness may be optimized for lower thermal resistance between the laser device 204, the heater device 205, and the cold plate 206.

The cold plate 206 may be formed of any suitable material that has sufficient structural strength to withstand the desired pressures of coolant flowing into the coolant chamber volume 210. For example, the cold plate 206 may be formed of semiconductor material like silicon or other materials like glass. In other examples, the cold plate 206 may be formed of a material selected from a group comprising polymers, metals, ceramics, or composites thereof. In some embodiments, the cold plate 206 may be formed of stainless steel (e.g., from a stainless steel metal sheet) or a sapphire plate.

In some embodiments, the cold plate 206 may be formed of a bulk material having a substantially similar CTE to the bulk material of the substrate 202, the laser device 204, and/or the heater device 205 where the CTE is a fractional change in length of the material (in the X-Y plane) per degree of temperature change. In some embodiments, the CTEs of the cold plate 206, the heater device 205, the laser device, the substrate 202, and/or the laser device 204 are matched so that the CTEs vary within about +/−20% or less, such as within +/−15% or less, within +/−10% or less, or within about +/−5% or less when measured across a desired temperature range. In some embodiments, the CTEs are matched across a temperature range from about −60° C. to about 100° C. or from about −60° C. to about 175° C. In one example embodiment, the matched CTE materials each include silicon.

In some embodiments, the cold plate 206 may be formed of a material having a substantially different CTE from the laser device 204 and the heater device 205, e.g., a CTE mismatched material. In such embodiments, the cold plate 206 may be attached to the laser device 204 and/or the heater device 205 by a compliant adhesive layer (not shown) or a molding material that absorbs the difference in expansion between the cold plate 206, the heater device 205 and/or the laser device 204 across repeated thermal cycles.

The package cover 208 shown in FIGS. 2C and 3 generally comprises one or more vertical or sloped sidewall portions 208A and a lateral portion 208B that spans and connects the sidewall portions 208A. The sidewall portions 208A may extend upwardly from a peripheral surface of the package substrate 202 to surround the device 204, the heater device 205, and the cold plate 206 disposed thereon. The lateral portion 208B may be disposed over the cold plate 206 and is typically spaced apart from the cold plate 206 by a gap corresponding to the thickness of the sealing material layer 222. The sealing material may be an adhesive or a gasket. In some embodiments, instead of or as well as the sealing material layer 222, a gasket may be used to seal a gap between the package cover 208 and the cold plate inlet/outlet openings. The gasket may be made of rubber (e.g., neoprene, nitrile, ethylene propylene diene monomer, or silicon rubber) or similar such material. For example, the gasket may be an o-ring. The gasket may be attached between a lower surface of the package cover 208 and an upper surface of the cold plate facing the package cover 208 using an adhesive. The gasket may provide a water tight seal to direct coolant fluid from the package cover 208 into the cold plate inlet/outlet openings while preventing coolant fluid from leaking onto exterior surfaces of the integrated thermal control assembly 203. In some embodiments, the package cover 208 is attached to one or more cold plates using one or more corresponding gaskets.

Coolant is circulated through the coolant channels 210 through the inlet and outlet openings 212 of the package cover 208 formed through the lateral portion 208B. The inlet and outlet openings 206A of the cold plate 206 may be in fluid communication with the inlet and outlet openings 212 of the package cover 208 through the inlet and outlet openings 222A formed in the sealing material layer 222 disposed therebetween. In certain embodiments, coolant lines 108 (FIGS. 2A-2B) may be attached to the device package 201 by use of connector features formed in the package cover 208, such as threads formed in the sidewalls of the inlet and outlet openings 212 of the package cover 208 and/or protruding features 214 that surround the inlet and outlet openings 212 and extend upwardly from a surface of the lateral portion 208B.

Typically, the package cover 208 is formed of semi-rigid or rigid material so that at least a portion of the downward force exerted on the package cover 208 by the mounting frame is transferred to a supporting surface of the package substrate 202 and not transferred to the cold plate 206 and the laser device 204 therebelow. In some embodiments, the package cover 208 is formed of a thermally conductive metal, such as aluminum or copper. In such embodiments, the package cover 208 functions as a heat spreader that redistributes heat from the laser device 204. In some embodiments, the package cover 208 and/or a manifold (such as the manifold discussed above) may consist of or comprise a thermally insulating material or materials. In such embodiments, the package cover 208 and/or the manifold may function as a thermal insulator to retain heat or cold. In some embodiments, the package cover 208 and/or the manifold may be insulating to minimize or reduce the flow of thermal energy (e.g., thermal flux) between components (e.g., semiconductor devices, semiconductor device stacks, device packages, etc.). For example, the package cover 208 and/or the manifold may minimize or reduce the flow of thermal energy between a first laser device and a second laser device. In another example, the package cover 208 and/or the manifold may minimize or reduce the flow of thermal energy between a first semiconductor device stack and a second semiconductor device stack. In another example, the package cover 208 and/or the manifold may minimize or reduce the flow of thermal energy between a first device package and a second device package. In another example, the package cover 208 and/or the manifold may minimize or reduce the flow of thermal energy between a laser device and a semiconductor device stack. In another example, the package cover 208 and/or the manifold may minimize or reduce the flow of thermal energy between a laser device of a device package and a second device package.

It should be noted that the direction in which the coolant fluid flows through the cold plate 206 may be controlled depending on the relative locations of the inlet and outlet openings. For example, the coolant fluid may flow from left to right in the device package 201 of FIG. 3 when the inlet openings 212, 222A, 206A of the package cover 208, the sealing material layer 222, and the cold plate 206, respectively, are located on the left-hand side of the device package 201 and the outlet openings 212, 222A, 206A of the package cover 208, the sealing material layer 222, and the cold plate 206, respectively, are located on the right-hand side of the device package 201. Alternatively, the coolant fluid may flow from right to left in the device package 201 illustrated in FIG. 3 when the outlet openings 212, 222A, 206A of the package cover 208, the sealing material layer 222, and the cold plate 206 are located on the left-hand side of the device package 201 and the inlet openings 212, 222A, 206A of the package cover 208, the sealing material layer 222, and the cold plate 206 are located on the right-hand side of the device package 201. Although only one set of inlet and outlet openings is shown and described here, additional inlet and outlet openings may also be provided at various locations on the package cover 208, the sealing material layer 222, and the cold plate 206.

An example flow path of the coolant fluid through the coolant channels 210 may be as follows:
1. Coolant fluid enters the coolant channels 210 through the inlet openings.
2. Coolant fluid flows across the inside surfaces of the cold plate 206 and absorbs heat generated by the laser device 204, via the heater device 205, which has dissipated into the cold plate 206 structure. The coolant fluid may also flow directly across the backside 205A of the heater device 205 to absorb heat energy directly from the heater device 205. The coolant channels 210 may have various channels formed to direct the coolant fluid flow from inlet opening(s) to outlet opening(s) and facilitate heat extraction from the laser device 204 by the coolant fluid. In some embodiments, the coolant fluid may be in direct contact with the backside 205A of the heater device 205 or via one or more substrates or layers between the coolant fluid and the backside 205A of the heater device 205.
3. Coolant fluid exits the coolant channels 210 through outlet openings.

It will be understood from the above flow path that heat is extracted without introducing an unnecessary thermal resistance (e.g., a TIM disposed between the backside 205 of the heater device 205 and the cold plate 206 and/or a TIM disposed between the frontside 205B of the heater device 205 and the backside 220 of the laser device 204).

FIG. 5 shows an isometric view of a representative cold plate 506. The cold plate 506 comprises three coolant channels 510A, 510B, 510C, which generally correspond to those shown as part of the cold plate 206 shown in FIG. 4. Therefore, description of like features will be omitted for brevity. The cold plate 506 of FIG. 5 further includes an inlet opening 506A an outlet opening 506A, between which the three coolant channels 510A, 510B, 510C extend laterally. As can be seen in FIG. 5, the coolant channels 510A, 510B, 510C take a generally triangular cross-section and extend along the cold plate 506 between the inlet opening 506A and the outlet opening 506A. However, it will be understood that the cross-section of the coolant channels 510A, 510B, 510C may take different shapes (e.g., trapezoidal, rectangular, etc.). In FIG. 5, the cold plate 506 includes three coolant channels 510A, 510B, 510C, but as described herein, the cold plate 506 may include more than three or less than three coolant channels 510A, 510B, 510C.

A fluid flow path 512 is shown in FIG. 5. The fluid flow path 512 enters the cold plate 506 via the inlet opening 506A, passes through the three coolant channels 510A, 510B, 510C, and exits out of the outlet opening 506A. In some examples, an inlet manifold may be included to split the fluid flow 512 between the coolant channels 510A, 510B, 510C from the inlet opening 506A. In some examples, an outlet manifold may be included to collect the fluid flow from the coolant channels 510A, 510B, 510C and pass the fluid flow 512 out of the outlet opening 506A. In some examples, each coolant channel 510A, 510B, 510C may have its own inlet and/or outlet.

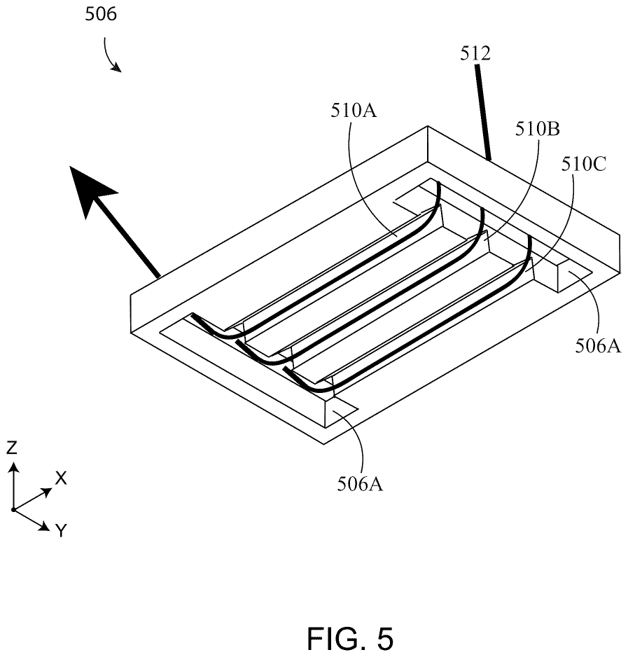

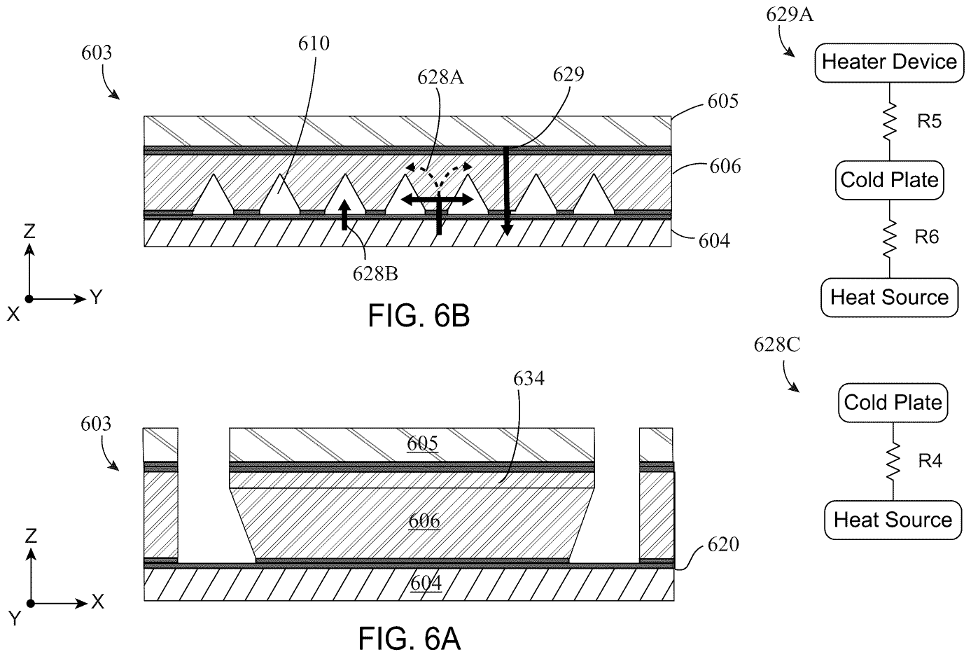

FIG. 6A is a schematic sectional view in the X-Z plane of an integrated thermal control assembly 603 and FIG. 6B is a schematic sectional view in the Y-Z plane of the integrated thermal control assembly 603, in accordance with embodiments of the present disclosure. The integrated thermal control assembly 603 may be similar to the integrated thermal control assembly 203 described above, and therefore the description of similar features is omitted for brevity.

The integrated thermal control assembly 603 comprises a laser device (or LED device) 604, a cold plate 606, and a heater device 605 which are vertically stacked with the cold plate 606 disposed between the laser device 604 and the heater device 605. Therefore, the integrated thermal control assembly 603 of FIGS. 6A and 6B differs from previous assemblies in that the cold plate 606 is disposed between the laser device 604 and the heater device 605. As shown, the heater device 605 is attached to a first side (e.g., top portion 634) of the cold plate 606, and the laser device 604 is attached to a second side (e.g., lower surfaces that are opposite the top portion 634) of the cold plate 606 opposite the first side of the cold plate 606. A backside 620 of the laser device 604 may be exposed to at least one coolant channel 610. That is, the backside 620 of the laser device 604 may be exposed to the coolant channels 610 such that heat dissipated by the laser device 604 may be absorbed by coolant fluid flowing through the coolant channels 610. In some embodiments (e.g., as shown in FIG. 6A), the cold plate 606 may be attached to the heater device 605 and the semiconductor device 604 by direct dielectric bonds or direct hybrid bonds, as discussed herein. The front side of the laser device 604 may be attached to a substrate (such as substrate 202) comprising an optical waveguide and optionally an interposer.

In FIG. 6B, arrows 628A, 628B, and 629 illustrate three different heat transfer paths of the integrated thermal control assembly 603. A first heat transfer path illustrated by arrow 628B shows heat generated by the laser device 604 transferring directly from the semiconductor material of the laser device 604 to coolant fluid flowing through the cold plate 606. A second heat transfer path illustrated by arrows 628A shows heat generated by the laser device (or LED device) 604 being transferred from semiconductor material of the laser device 604 to semiconductor material of the cold plate 606 structure, propagating throughout the semiconductor material of the cold plate 606 structure (shown as dashed lines), and being transferred into coolant fluid flowing through the cold plate 606. A third heat transfer path illustrated by arrow 629 shows heat which is purposely generated by the heater device 605 being transferred from the resistive wire and/or the one or more resistors of the heater device 605 to the laser device 604 therebelow, via the cold plate 606 structure. A thermal resistance of the first and second heat transfer paths 628A, 628B is illustrated by heat transfer path 628C, which is shown as a fourth thermal resistance R4 between the cold plate 606 and the heater device 605. A thermal resistance of the third heat transfer path is illustrated by heat transfer path 629A, which is shown as an arrangement of a fifth thermal resistance R5 between a heater device and a cold plate, and a sixth thermal resistance R6 between the cold plate and the heat source. It can be seen that the heat transfer paths of the integrated thermal control assembly 603 are reduced compared to the heat transfer path 26 of the device package 10 of FIG. 1, due to the direct bonding discussed above.

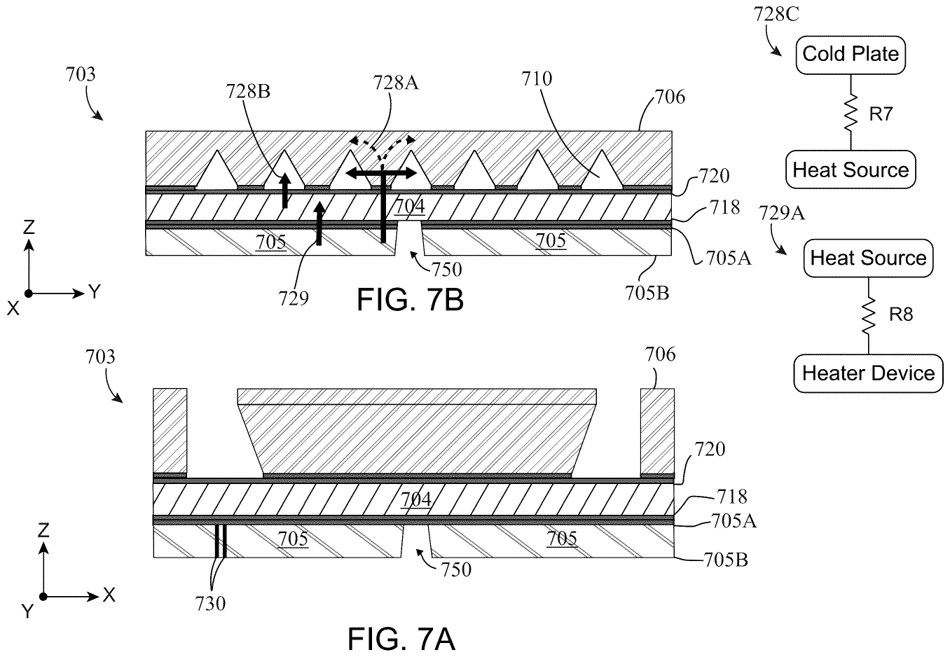

FIG. 7A is a schematic sectional view in the X-Z plane of an integrated thermal control assembly 703 and FIG. 7B is a schematic sectional view in the X-Z plane of the integrated thermal control assembly 703, in accordance with embodiments of the present disclosure. The integrated thermal control assembly 703 may be similar to the integrated thermal control assembly 203 described above, and therefore the description of similar features is omitted for brevity.

The integrated thermal control assembly 703 comprises a laser device 704, a cold plate 706, and a heater device 705, which are vertically stacked with the laser device 704 disposed between the cold plate 706 and the heater device 705. Therefore, the integrated thermal control assembly 703 of FIGS. 7A and 7B differs from previous assemblies in that the laser device 704 is disposed between the cold plate 706 and the heater device 705. As shown, the heater device 705 is attached to a frontside 718 of the laser device 704, and the cold plate 706 is attached to a backside 720 of the laser device 704 opposite the frontside of the laser device 704. The backside 720 of the laser device 704 is exposed to at least one coolant channel 710. That is, the backside 720 of the laser device 704 may be exposed to the coolant channels 710 such that heat dissipated by the laser device 704 may be absorbed by coolant fluid flowing through the coolant channels 710. In order to provide electrical connections from the laser device 704 to a substrate, interposer, and/or waveguide therebelow (not shown), through substrate vias (TSVs) 730 may be provided through the structure of the heater device 705, as shown in FIG. 7A. The TSVs 730 may provide power and/or signals to the laser device 704. Furthermore, a redistribution layer (RDL) may be provided adjacent to the laser device 704 and/or the heater device 705.

In some embodiments (e.g., as shown in FIG. 7A), the laser device 704 is attached to the heater device 705 and the cold plate 706 by direct dielectric bonds or direct hybrid bonds, as discussed herein. The laser device 704 may be attached to a first side (e.g., backside 705A) of the heater device 705 and a substrate (such as substrate 202) comprising an optical waveguide and optionally an interposer (not shown) may be attached to a second side (e.g., frontside 705B) of the heater device 705 opposite the first side of the heater device 705. The optical waveguide may be substantially similar to the optical waveguide 202 described above in relation to FIG. 3. Here, the heater device 705 comprises an internal sidewall defining a cavity 750 to expose a portion of the laser device (or LED device) 704 to a portion of the optical waveguide to allow optical coupling of the laser or LED device and the optical waveguide. In FIGS. 7A and 7B, the cavity 750 is illustrated as a rectangular cavity (in the X-Y plane) in the center of the heater device 705, with tapered sidewalls (i.e., the cross-sections are taken through substantially the center of the stack on both planes). However, it will be understood that the cavity 750 may be disposed anywhere in the heater device 705 to allow for transmitting a light (e.g., a monochromatic light comprising a relatively-low wavelength range such as a light emitted by a laser) from the laser device 704 through the cavity 750 towards the optical waveguide. Advantageously, in the arrangement illustrated in FIG. 7B, the laser device 704 is disposed directly adjacent to the cold plate 706 and to the heater device 705, with no intervening devices or substrates therebetween, which may result in more responsive control of the laser device 704 temperature. Although the cavity 750 is illustrated as a rectangular cavity in the center of the heater device 705, it could be of any other shape (e.g. cylindrical, conical, truncated conical, pyramid, prism, etc.) and may be located closer to the edges of heater device 705 than the center. Although, FIGS. 7A and 7B depicts only one cavity 750, more than one such cavity may also be present (e.g. two, four, six, eight, twelve, sixteen, etc. cavities).

In FIG. 7B, arrows 728A, 728B, and 729 illustrate three different heat transfer paths of the integrated thermal control assembly 703. First and second heat transfer paths illustrated by arrows 728B and 728A, respectively, substantially correspond to the first and second heat transfer paths 228B, 228A described above in relation to FIG. 4. Therefore, description of the first and second heat transfer paths 728B, 728B will be omitted for brevity. A third heat transfer path illustrated by arrow 729 shows heat which is purposely generated by the heater device 706 being directly transferred from the resistive wire and/or the one or more resistors of the heater device 705 to the laser device 704. A thermal resistance of the first and second heat transfer paths 728A, 728B is illustrated by heat transfer path 728C, which is shown as a seventh thermal resistance R7 between a cold plate and a heater device. A thermal resistance of the third heat transfer path is illustrated by heat transfer path 729A, which is shown as a eighth thermal resistance R8 between a heater device and a heat source. It can be seen that the heat transfer paths of the integrated thermal control assembly 703 are reduced compared to the heat transfer path 26 of the device package 10 of FIG. 1, due to the direct bonding discussed above.

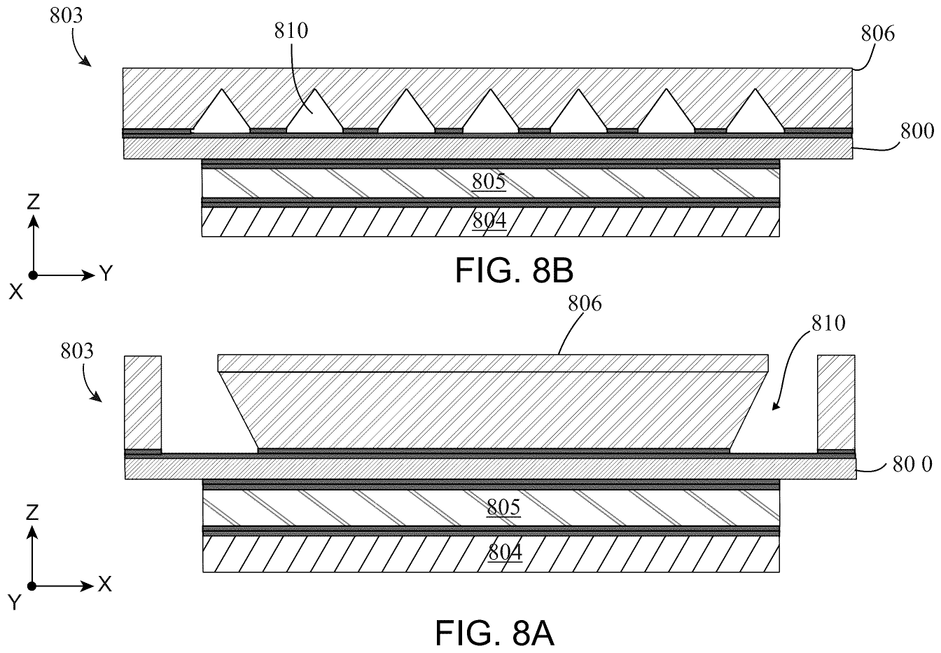

FIG. 8A is a schematic sectional view in the X-Z plane of an integrated thermal control assembly 803 and FIG. 8B is a schematic sectional view in the Y-Z plane of the integrated thermal control assembly 803, in accordance with embodiments of the present disclosure. The integrated thermal control assembly 803 may be similar to the integrated thermal control assembly 203 described above, and therefore the description of similar features is omitted for brevity.

In FIG. 8A, a width of the cold plate 806 in a first direction is greater than a width of the heater device 805 and a width of the laser device 804 in the first direction. The first direction is taken to be a direction perpendicular to a second direction in which the perimeter sidewall extends. With reference to FIGS. 8A and 8B, the second direction is the Z-axis direction and the first direction is either the X-axis or the Y-axis direction. Here, the width of the cold plate 806 is greater than the widths of the heater device 805 and the laser device 804 in both the X-axis direction and the Y-axis direction. In embodiments of FIGS. 8A and 8B where the laser device 804 and the heater device 805 have rectangular footprints, the cold plate 806 extends beyond all four sidewalls of the heater device 805 and the laser device 804. However, it will be understood that the width of the cold plate 806 in the first direction may be greater than only the width of the heater device 805 in the first direction, or only the width of the laser device 804 in the first direction.

In order to provide a cold plate 806 having a width greater than widths of the heater device 805 and/or the laser device 804, a structural substrate 800 having substantially the same width (in the X-axis direction and the Y-axis direction) as the cold plate 806 is provided between the cold plate 806 and the heater device 805. The structural substrate 800 provides structural rigidity to overhanging portions of the cold plate 806 and also closes portions of coolant channels 810 in the overhanging portions which would otherwise be exposed. The structural substrate 800 may be attached between the cold plate 806 and the heater device 805 using direct bonding techniques described herein.

It will be understood that the relative positions of the cold plate 806, the heater device 805, and the laser device 804 may be swapped in the integrated thermal control assembly 803, similar to the arrangements shown in FIGS. 6A, 6B, 7A and 7B. For example, a substrate (such as substrate 202) comprising an optical waveguide and optionally an interposer (not shown) may be attached to a frontside of the laser device 804.

Advantageously, by increasing the width of the cold plate 806 in the X-axis direction and/or the Y-axis direction, as described above, additional coolant channels 810 may be introduced to the cold plate 806 in order to increase the efficiency of thermal cooling.

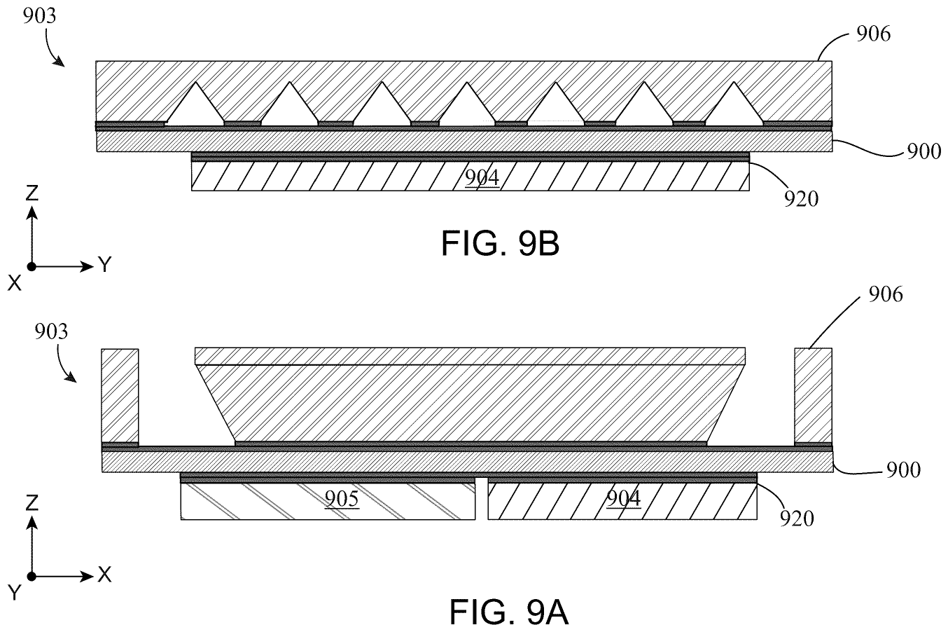

FIG. 9A is a schematic sectional view in the X-Z plane of an integrated thermal control assembly 903 and FIG. 9B is a schematic sectional view in the Y-Z plane of the integrated thermal control assembly 903, in accordance with embodiments of the present disclosure. The integrated thermal control assembly 903 may be similar to the integrated thermal control assemblies 203 and 803 described above, and therefore the description of similar features is omitted for brevity.

Here, the integrated thermal control assembly 903 comprises a laser device (or LED device) 904 disposed laterally adjacent to the heater device 905, and the cold plate 906 is attached to a first side (e.g., backside 905A) of the heater device 905 and a first side (e.g., backside 920) of the laser device 904. That is, the cold plate 906 is attached (e.g., by direct bonding), via a structural substrate 900, to the upper surfaces of both the heater device 905 and the laser device 904, such that the vertical height of the device stack in the Z-axis direction is reduced compared to that of the integrated thermal control assembly 803 of FIGS. 8A and 8B.

Similar to the arrangement illustrated in FIGS. 8A and 8B, a width of the cold plate 906 in a first direction is greater than a combined width of the heater device 905 and the laser device 904 in the first direction. The structural substrate 900 having substantially the same width (in the X-axis direction and the Y-axis direction) as the cold plate 906 is provided in a similar manner to the integrated thermal control assembly 803 of FIGS. 8A and 8B. A substrate (such as substrate 202) comprising an optical waveguide and optionally an interposer (not shown) may be attached to a frontside of the laser device 904 and the heater device 905.

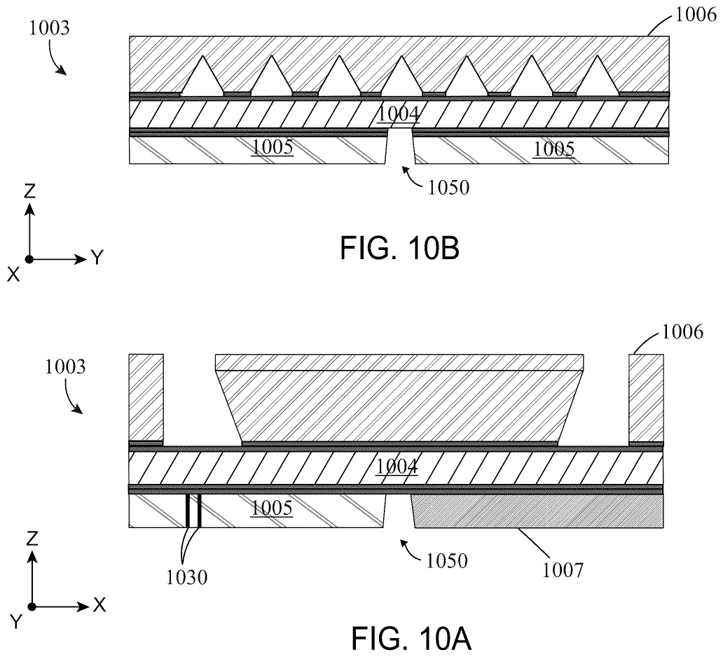

FIG. 10A is a schematic sectional view in the X-Z plane of an integrated thermal control assembly 1003 and FIG. 10B is a schematic sectional view in the Y-Z plane of the integrated thermal control assembly 1003, in accordance with embodiments of the present disclosure. The integrated thermal control assembly 1003 may be similar to the integrated thermal control assembly 203 described above, and therefore the description of similar features is omitted for brevity.

The integrated thermal control assembly 1003 comprises a laser device 1004, a cold plate 1006, and a heater device 1005 which are vertically stacked with the laser device 1004 disposed between the cold plate 1006 and the heater device 1005. The integrated thermal control assembly 1003 further comprises a thermoelectric cooler (TEC) 1007 disposed adjacent to the heater device 1005, the laser device 1004, and the cold plate 1006, as shown. In some instances, the TEC 1007 may be able to adjust (e.g., increase or decrease) a temperature of the laser device 1004 (e.g., in operation or idle), of a few degrees or more to maintain the temperature of the laser device 1004 within an optimum temperature range. The fine granularity of temperature control provided by the TEC 1007 enables the TEC 1007 footprint to be smaller than the footprint of the laser device 1004 and the cold plate 1006. In some embodiments, the footprint of the TEC 1007 is larger than the footprint of the laser device (or LED device) 1004 and smaller than the footprint of the cold plate 1006. The TEC 1007 may be attached to the laser device 1004 by direct bonding, as discussed herein. In some embodiments, only the TEC 1007 is attached (e.g. direct or hybrid bonded) to the laser device (or LED device) 1004 and no separate heater device is attached to the laser device (or LED device) 1004. A substrate (such as substrate 202) comprising an optical waveguide and optionally an interposer (not shown) may be attached to a frontside of the TEC 1007 and the heater device 1005. In order to provide electrical connections from the laser device 1004 to a substrate, interposer, and/or waveguide therebelow (not shown), through substrate vias (TSVs) 1030 may be provided through the structure of the heater device 1005, as shown in FIG. 10A. The TSVs 1030 may provide power and/or signals to the laser device 1007. Furthermore, a redistribution layer (RDL) may be provided adjacent to the laser device 1007 and/or the heater device 1005.

In FIGS. 7A and 7B, a cavity 1050 is illustrated as a rectangular cavity (in the X-Y plane) in the center of the heater device 1005 and between the heater device 1005 and the TEC 1007. The cavity 1050 may be similar to the cavity 750 described above with reference to FIGS. 7A and 7B. In particular, although the cavity 1050 is illustrated as a rectangular cavity, it could be of any other shape (e.g. cylindrical, conical, truncated conical, pyramid, prism, etc.) and may be located closer to the edges of heater device 1005 than the center. Although, FIGS. 10A and 10B depicts only one cavity 1050, more than one such cavity may also be present (e.g. two, four, six, eight, twelve, sixteen, etc. cavities).

In some embodiments, the TEC may be disposed adjacent to at least one coolant channel of the cold plate 1006 above the laser device 1004 (e.g., such that the TEC is disposed within at least one coolant channel).

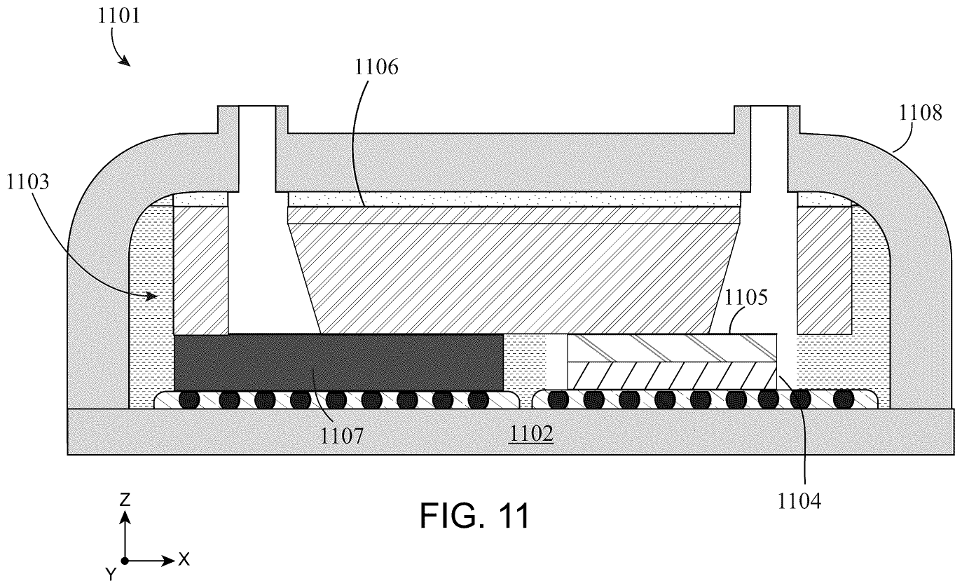

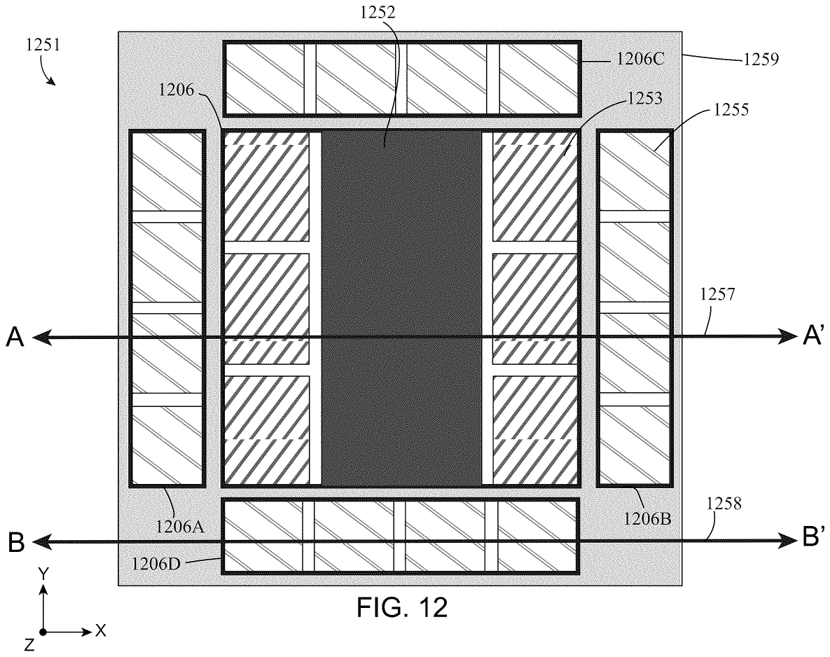

FIG. 11 is a schematic sectional view in the X-Z plane of a device package 1101 including an integrated thermal control assembly 1103. The integrated thermal control assembly 1103 includes a cold plate 1106, a laser device 1104 (e.g., a first semiconductor device), a heater device 1105, and a second semiconductor device 1107. Here, a combined vertical height of a stack comprising the heater device 1105 and the laser device 1104 is substantially the same (in the Z-axis direction) as a height of the second semiconductor device 1107. The second semiconductor device 1107 is disposed laterally adjacent to the stacked heater device 1105 and laser device 1104 and the cold plate 1106 is attached above (e.g., by direct bonds) both the semiconductor device 1107 and the heater device 1105. Therefore, the coolant channels of the cold plate 1106 extend across backsides of both the heater device 1105 and the second semiconductor device 1107. It will be understood that the arrangement of the heater device 1105 and the laser device 1104 may be swapped, as described above. Furthermore, the vertically stack comprising the heater device 1105 and laser device 1104 may also comprise a PIC. Although FIG. 11 illustrates the laser device 1104 is attached to a substrate 1102 using flip chip technology, the laser device 1104 may alternatively be attached to the substrate 1102 by direct bonding or hybrid bonding, as described herein.

The second semiconductor device 1107 may comprise at least one of: a GPU, a CPU, a NPU, a TPU, and ASIC and/or a memory stack (e.g., HBM). Although FIG. 11 depicts only one second semiconductor device 1107 attached to the substrate 1102 (e.g. interposer or waveguide), more than one such second semiconductor device 1107 (e.g. two GPUs and twelve HBMs) may be attached to the interposer along with the stack comprising the heater device 1105 and the laser device 1104.

As shown, sidewalls of the laser device 1104 may be directly exposed to at least one of the coolant channels. Advantageously, by exposing sidewalls of the laser device 1104, the efficiency of thermal control can be improved by exposing an increased surface area of the laser device 1104 to coolant fluid.

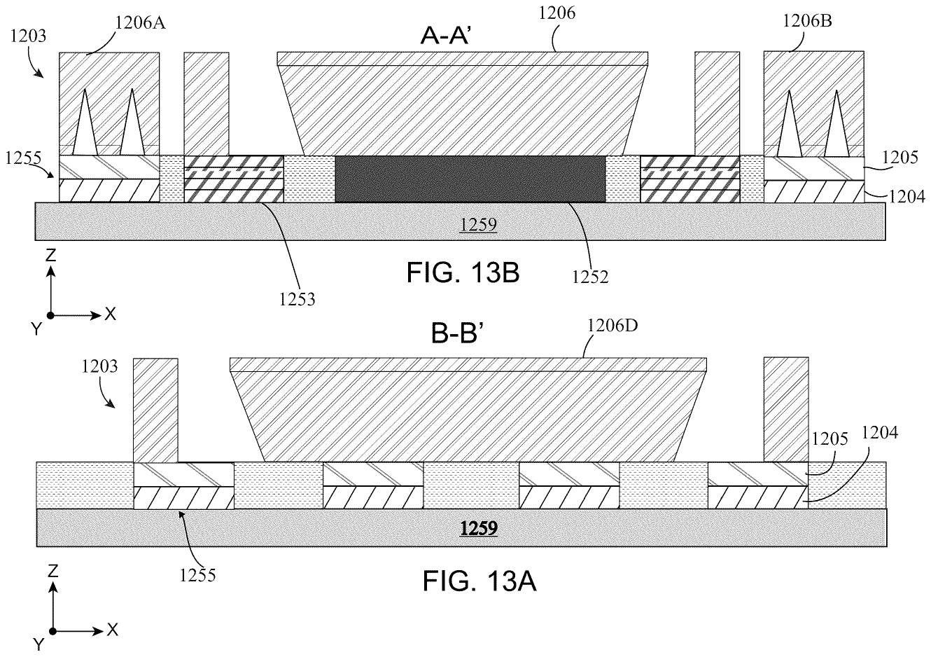

FIG. 12 is a plan view of an arrangement 1251 including a GPU 1252 (e.g., a second semiconductor device), multiple HBMs 1253 (e.g., a stack of HBMs), and multiple co-packaged optics (CPOs) 1255 (e.g., a first semiconductor device), in accordance with embodiments of the present disclosure. The CPOs 1255 are disposed laterally adjacent to the GPU 1252 and the HBM 1253. FIG. 12 includes a cross-section A-A′ line 1257 and a cross-section B-B′ line 1258, each of which are depicted in detail in FIGS. 13B and 13A, respectively. Each CPO 1255 may include a heater device 1205 vertically stacked on a laser device (or LED device) 1204, as illustrated in FIGS. 13A and 13B. In FIGS. 13A and 13B, in a CPO 1255, the heater device 1205 is disposed in between the cold plate 1206P, 1206Q, 1206R, 1206S, and the laser device 1204. The relative positions of the heater device 1205 and the laser device 1204 in a CPO 1255 may be swapped, for example, when the heater device 1205 comprises an internal sidewall defining a cavity to expose a portion of the laser device 1204 to a portion of an optical waveguide. The CPOs 1255 may further comprise a PIC, as described above in relation to FIG. 11. The GPU, 1252, the HBMs 1253, and the CPOs 1255 may be disposed on a substrate 1259, such as an interposer or an optical waveguide. The arrangement 1251 may further comprise separate cold plates for cooling different portions of the arrangement 1251. As shown, a first cold plate 1206 may be attached to backsides (e.g., vertically adjacent) of the GPU 1252 and the HBMs 1253, a second cold plate 1206A may be attached to backsides (e.g., vertically adjacent) of a first group of CPOs 1255 on the left hand side of the arrangement 1251, a third cold plate 1206B may be attached to backsides of (e.g., vertically adjacent) a second group of CPOs 1255 on the right hand side of the arrangement 1251, a fourth cold plate 1206C may be attached to backsides of (e.g., vertically adjacent) a third group of CPOs at the top of the arrangement 1251, and a fifth cold plate 1206D may be attached to backsides of (e.g., vertically adjacent) a fourth group of CPOs at the bottom of the arrangement 1251. The cold plates are disposed laterally adjacent to each other. In some embodiments, the second, third, fourth, and fifth cold plates 1206A, 1206B, 1206C, and 1206D are connected together by a shared manifold.

Advantageously, by providing separate cold plates for different types of components, a temperature of different components can be controlled independently of each other. For example, where the GPU 1252 and HBM 1253 are operating at a high level of performance, and generally operating at slightly higher temperature (e.g. 80 C to 120 C) than the laser or LED, the first cold plate 1206 can provide maximum cooling to the GPU 1252 and the HBMs 1253 without inadvertently lowering the temperature of the laser device of the CPOs 1255 outside of an optimum temperature range. Conversely, by providing dedicated heaters (e.g., heater devices 1205) to each laser of separate CPOs 1255, the heaters will not cause undesirable temperature rise in the GPU 1252 and the HBMs 1253.

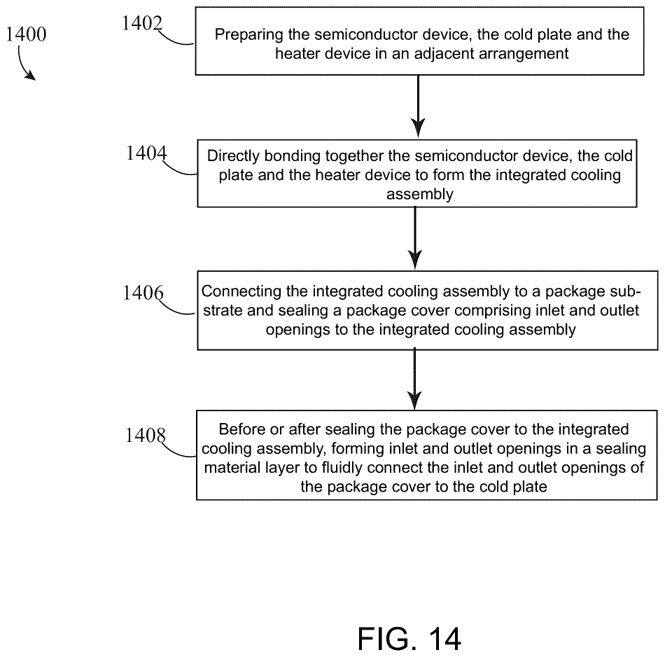

FIG. 14 is a flow diagram showing a method 1400 of forming an integrated thermal control assembly, according to embodiments of the present disclosure. Generally, the method 1400 includes bonding a first substrate comprising one or more cold plates to a second substrate comprising one or more laser devices, and/or to a third substrate comprising one or more heater devices, in an adjacent arrangement, and singulating one or more integrated thermal control assemblies from the bonded first, second, and/or third substrates. For example, a wafer (bare or reconstituted wafer) comprising one or more cold plates can be directly bonded to another wafer (bare or reconstituted wafer) comprising one or more laser devices, and/or to a third wafer comprising one or more heater devices.

It will be understood that the first substrate may be a cold plate die or part of a wafer of cold plates. Further, the second substrate may be a laser device die or part of a wafer of laser devices. Further, the third substrate may be a heater device die or part of a wafer of heater devices. Therefore, the method 1400 may include die-to-die direct bonding (e.g., cold plate die to laser device die and/or to heater device die), wafer-to-die direct bonding (e.g., cold plate die to laser device wafer and/or heater device wafer, or cold plate wafer to laser device die and/or heater device die), and wafer-to-wafer direct bonding (e.g., cold plate wafer to laser device wafer and/or heater device wafer). It will be understood that the singulation step may not be required for a die-to-die direct bonding operation.

For simplicity, the following description is focused on forming one integrated thermal control assembly comprising one cold plate, one laser device and one heater device. However, as mentioned above, in some embodiments, the first substrate may comprise plural cold plates, the second substrate may comprise plural semiconductor devices, and the third substrate may comprise plural heater devices such that plural integrated thermal control assemblies may be formed from the first, second and third substrates.

In particular, at block 1402, the method 1400 includes preparing the semiconductor device, the cold plate, and the heater device, in an adjacent arrangement.

At block 1404, the method 1400 includes directly bonding together the first substrate (e.g., a monocrystalline silicon wafer) comprising a cold plate, the second substrate (e.g., a monocrystalline silicon wafer) comprising a semiconductor device, and the third substrate (e.g., a monocrystalline silicon wafer) comprising a heater device. By direct bonding, it is meant that the bond is effected without an intervening adhesive.

In some embodiments, the first substrate may be etched using a patterned mask layer formed on its surface to form features of the cold plate. An anisotropic etch process may be used, which uses inherently differing etch rates for the silicon material as between {100} plane surfaces and {111} plane surfaces when exposed to an anisotropic etchant

In some embodiments, the etching process is controlled to where a ratio of the etch rate in the {1000} plane to the etch rate in the {111} plane is between about 1:10 and about 1:200, such as between about 1:10 and about 1:100, for example between about 1:10 and 1:50, or between about 1:25 and 1:75. Examples of suitable anisotropic wet etchants include aqueous solutions of potassium hydroxide (KOH), ethylene diamine and pyrocatechol (EPD), ammonium hydroxide (HN₄OH), hydrazine (N₂H₄), or tetra methyl ammonium hydroxide (TMAH). The actual etch rates of the silicon substrate depend on the concentration of the etchant in the aqueous solution, the temperature of the aqueous solution, and a concentration of the dopant in the substrate (if any). Typically, the mask layer is formed of a material that is selective to anisotropic etch compared to the underlying monocrystalline silicon substrate. Examples of suitable mask materials include silicon oxide (SiₓO_{y}) or silicon nitride (SiₓN_{y}). In some embodiments, the mask layer has a thickness of about 100 nm or less, such as about 50 nm or less, or about 30 nm or less. The mask layer may be patterned using any suitable combination of lithography and material etching patterning methods.

The second and/or third substrates may include a bulk material, and a plurality of material layers disposed on the bulk material. The bulk material may include any semiconductor material suitable for manufacturing semiconductor devices, such as silicon, silicon carbide, silicon germanium, germanium, group III-V semiconductor materials, group II-VI semiconductor materials, or combinations thereof. While some high-performance processors like CPUs, GPUS, NPUs, and TPUs are typically made out of silicon, some other high power density (hence substantial heat-generating) devices may comprise silicon carbide or gallium nitride, for example. In some embodiments, the second and/or third substrates may include a monocrystalline wafer, such as a silicon wafer, a plurality of device components formed in or on the silicon wafer, and a plurality of interconnect layers formed over the plurality of device components. In other embodiments, the second and/or third substrate may comprise a reconstituted substrate, e.g., a substrate formed from a plurality of singulated devices embedded in a support material. In some embodiments, each semiconductor device may have its own individual cold plate fabricated through a reconstitution process.

The bulk material of the second and/or third substrates may be thinned after the laser device and/or heater device is formed using one or more backgrinding, etching, and polishing operations that remove material from the backside. Thinning the substrates may include using a combination of grinding and etching processes to reduce the thickness (in the Z-direction) to about 450 μm or less, such as about 200 μm or less, or about 150 μm or less or about 50 μm or less. After thinning, the backside(s) may be polished to a desired smoothness using a chemical mechanical polishing (CMP) process, and the dielectric material layer may be deposited thereon. In some embodiments, the dielectric material layer may be polished to a desired smoothness to prepare the substrates for the bonding process. In some embodiments, the method 1400 includes forming a plurality of metal features in the dielectric material layer in preparation for a hybrid bonding process, such as by use of a damascene process.

In some embodiments, the active side of the substrates is temporarily bonded to a carrier substrate (not shown) before the thinning process. When used, the carrier substrate provides support for the thinning operation and/or for the thinned material to facilitate substrate handling during one or more of the subsequent manufacturing operations described herein.

Generally, directly bonding the surfaces (of the dielectric material layers formed on the first, second, and third substrates) includes preparing, aligning, and contacting the surfaces. Examples of dielectric material layers include silicon oxide, silicon nitride, silicon oxynitride, and silicon carbonitride. Preparing the surfaces may include smoothing the respective surfaces to a desired surface roughness, such as between 0.1 to 3.0 nm RMS, activating the surfaces (e.g., a “very slight etch” using plasma or wet chemical treatment as taught in U.S. Pat. No. 6,902,987) to weaken or open chemical bonds in the dielectric material, and terminating the surfaces with a desired species (e.g., also as described in U.S. Pat. No. 6,902,987). Smoothing the surfaces may include polishing the first, second and third substrates using a CMP process. Simultaneously, activating and terminating the surfaces with a desired species may include exposing the surfaces to radical species formed in a plasma. The bond interface between the bonded dielectric layers can include a higher concentration of materials from the activation and/or last chemical treatment processes compared to the bulk of the bonding layers. For example, in some embodiments that utilize a nitrogen plasma for activation that terminates the bonding surface with a nitrogen-containing species, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. Such an oxygen concentration peak will be more detectable when the bonding layers do not contain oxygen, such as layers containing silicon nitride or silicon carbon nitride.

In some embodiments, the plasma is formed using a nitrogen-containing gas, e.g., N₂, and the terminating species includes nitrogen, or nitrogen and hydrogen. In some embodiments, fluorine may also be present within the plasma. In some embodiments, the surfaces may be activated using a wet cleaning or etching process, e.g., by exposing the surfaces to an aqueous ammonia solution (e.g., ammonium hydroxide). In some embodiments, the dielectric bonds may be formed using a dielectric material layer deposited on only one of the first, second and third substrates, but not on both. In those embodiments, the direct dielectric bonds may be formed by contacting the deposited dielectric material layer of one of the substrates directly with a bulk material surface (or such a surface with a native oxide) of the other substrate.

Directly forming direct dielectric bonds between the substrates at block 1404 may include bringing the prepared and aligned surfaces into direct contact at a temperature less than 150° C., such as less than 100° C., for example, less than 30° C., or about room temperature, e.g., between 20° C. and 30° C. Without intending to be bound by theory, in the case of directly bonding surfaces terminated with nitrogen and hydrogen (e.g., NH₂ groups), it is believed that a chemical bond is formed in part from the nitrogen species, wherein hydrogen gas byproducts (H₂ gas) of the chemical reaction diffuse away from the interfacial bonding surfaces. In some embodiments, the direct bond is strengthened using an anneal process, where the substrates are heated to and maintained at a temperature of greater than about 30° C. and less than about 450° C., for example, greater than about 50° C. and less than about 250° C., or about 150° C., for a duration of about 5 minutes or more, such as about 15 minutes. Typically, the bonds will strengthen over time even without the application of heat. Thus, in some embodiments, the method does not include heating the substrates.

In embodiments where the substrates are bonded using hybrid dielectric and metal bonds, the method 1400 may further include planarizing or recessing the metal features below the dielectric field surface before contacting and bonding the dielectric material layers. After the dielectric bonds are formed, the substrates may be heated to a temperature of 150° C. or more and maintained at the elevated temperature for a duration of about 1 hour or more, such as between 8 and 24 hours, to form direct metallurgical bonds between the metal features.

Suitable direct dielectric and hybrid bonding technologies that may be used to perform aspects of the methods described herein include ZiBond® and DBI®, each of which are commercially available from Adeia Holding Corp., San Jose, CA, USA.

At block 1406, the method 1400 may include connecting the integrated thermal control assembly, to the package substrate and sealing a package cover comprising inlet and outlet openings to the integrated thermal control assembly by use of a sealing material layer, such as a molding compound that is cured.

At block 1408, the method 1400 may include, before or after sealing the package cover to the integrated thermal control assembly forming inlet and outlet openings in the sealing material layer, to fluidly connect the inlet and outlet openings, of the package cover, to the cold plate.

The embodiments discussed above are intended to be illustrative and not limiting. One skilled in the art would appreciate that individual aspects of the integrated thermal control assemblies, device packages, and methods discussed herein may be omitted, modified, combined, and/or rearranged without departing from the scope of the disclosure.

1. (canceled)

2. An apparatus comprising:
a substrate;
a semiconductor device disposed on the substrate;
a cold plate directly bonded to the semiconductor device;
a laser device disposed on the substrate; and
a heater device disposed on the laser device.

3. The apparatus of claim 2, wherein the laser device is a laser diode, a fabry-perot laser, a distributed feedback laser, a vertical cavity surface-emitting laser, or a quantum dot laser.

4. The apparatus of claim 3, wherein the cold plate comprises:
a perimeter sidewall;
a top portion;
a cavity divider; and
coolant channels, wherein the perimeter sidewall and the cavity divider extend downwardly from the top portion to define portions of the coolant channels.

5. The apparatus of claim 3, wherein the semiconductor device comprises at least one of: a graphics processing unit (GPU), a central processing unit (CPU), a neural processing unit (NPU), a tensor processing unit (TPU), and high bandwidth memory (HBM).

6. The apparatus of claim 3, wherein the semiconductor device is an additional laser device.

7. The apparatus of claim 3, wherein the semiconductor device is a light emitting diode (LED) device.

8. The apparatus of claim 3, wherein the semiconductor device is a micro-electromechanical systems (MEMs) device.

9. The apparatus of claim 3, wherein the cold plate and the heater device collectively control a temperature of the laser device.

10. The apparatus of claim 9, wherein the cold plate and the heater device collectively control the temperature of the laser device to remain within a predetermined range of 50 degrees Celsius to 75 degrees Celsius.

11. The apparatus of claim 3, wherein the cold plate is directly bonded to the semiconductor device by direct dielectric bonds or direct hybrid bonds.

12. The apparatus of claim 3, wherein the cold plate is directly bonded to the heater device by direct dielectric bonds or direct hybrid bonds.

13. The apparatus of claim 3, further comprising an optical waveguide disposed adjacent to the laser device.

14. An apparatus comprising:
a substrate;
a semiconductor device disposed on the substrate;
a cold plate directly bonded to the semiconductor device;
a light emitting diode (LED) device disposed on the substrate; and
a heater device disposed on the LED device.

15. The apparatus of claim 14, wherein the cold plate comprises:
a perimeter sidewall;
a top portion;
a cavity divider; and
coolant channels, wherein the perimeter sidewall and the cavity divider extend downwardly from the top portion to define portions of the coolant channels.

16. The apparatus of claim 14, wherein the semiconductor device comprises at least one of: a graphics processing unit (GPU), a central processing unit (CPU), a neural processing unit (NPU), a tensor processing unit (TPU), and high bandwidth memory (HBM).

17. The apparatus of claim 14, wherein the semiconductor device is a laser diode, a fabry-perot laser, a distributed feedback laser, a vertical cavity surface-emitting laser, or a quantum dot laser.

18. The apparatus of claim 14, wherein the semiconductor device is an additional LED device.

19. The apparatus of claim 14, wherein the semiconductor device is a micro-electromechanical systems (MEMs) device.

20. The apparatus of claim 14, wherein the cold plate is directly bonded to the semiconductor device by direct dielectric bonds or direct hybrid bonds.

21. The apparatus of claim 14, wherein the cold plate is directly bonded to the heater device by direct dielectric bonds or direct hybrid bonds.
